(19) United States
(12) Patent Application Publication
(10) Pub. No.: US 2025/0191982 A1
(43) Pub. Date: Jun. 12, 2025

(54) TECHNIQUES FOR IN-SITU TESTING OF STACKED SEMICONDUCTOR COMPONENTS

(71) Applicant: Micron Technology, Inc., Boise, ID (US)

(72) Inventor: Yeon Seung Jung, Meridian, ID (US)

(21) Appl. No.: 18/970,678

(22) Filed: Dec. 5, 2024

Related U.S. Application Data
(60) Provisional application No. 63/609,296, filed on Dec. 12, 2023.

(51) Int. Cl. H01L 21/66; H01L 25/18; H10B 80/00

(52) U.S. Cl. CPC H01L 22/32; H01L 25/18; H10B 80/00

(57) ABSTRACT

Methods, systems, and devices for techniques for in-situ testing of stacked semiconductor components are described. A semiconductor system may include a semiconductor unit formed by a first component and one or more second components bonded with a second surface of a first component opposite to a first surface of the first component. The first component may include one or more conductors coupled (e.g., electrically, communicatively) with first circuitry, where each of the conductors may have a respective first interface at the first surface and a respective second interface at another surface of the first component. Each of the one or more second components may include respective second circuitry coupled with the first circuitry and may be configured to be operable based on signaling received via at least one of the one or more conductors of the first component.

### CROSS REFERENCE

The present Application for Patent claims priority to provisional U.S. Patent Application No. 63/609,296 by Jung, entitled “TECHNIQUES FOR IN-SITU TESTING OF STACKED SEMICONDUCTOR COMPONENTS,” filed Dec. 12, 2023, which is assigned to the assignee hereof, and which is expressly incorporated by reference in its entirety herein.

### TECHNICAL FIELD

The following relates to one or more systems for memory, including techniques for in-situ testing of stacked semiconductor components.

### BACKGROUND

Memory devices are used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored by the memory cell. To access stored information, a memory device may read (e.g., sense, detect, retrieve, determine) states from the memory cells. To store information, a memory device may write (e.g., program, set, assign) states to the memory cells.

Some memory devices may include a stack or other arrangement of semiconductor dies. However, some implementations of such arrangements may impair an ability to evaluate functionality of one or more dies of the stack, such as during manufacturing operations.

### BRIEF DESCRIPTION OF THE DRAWINGS

FIG. 1 shows an example of a system that supports techniques for in-situ testing of stacked semiconductor components in accordance with examples as disclosed herein.

FIG. 2 shows an example of a system that supports techniques for in-situ testing of stacked semiconductor components in accordance with examples as disclosed herein.

FIG. 3 shows an example of an interface architecture that supports techniques for in-situ testing of stacked semiconductor components in accordance with examples as disclosed herein.

FIG. 4 shows an example of a semiconductor system that supports techniques for testing of stacked semiconductor components in accordance with examples as disclosed herein.

FIGS. 5-8 show examples of operations for forming a semiconductor system that support techniques for in-situ testing of stacked semiconductor components in accordance with examples as disclosed herein.

FIGS. 9A-9C show examples of semiconductor units that support techniques for in-situ testing of stacked semiconductor components in accordance with examples as disclosed herein.

FIG. 10 shows a flowchart illustrating a method or methods that support techniques for in-situ testing of stacked semiconductor components in accordance with examples as disclosed herein.

### DETAILED DESCRIPTION

Some semiconductor systems (e.g., memory systems, processor systems) may include a stack of semiconductor dies, which may include one or more memory dies (e.g., array dies) or one or more stacks of memory dies that are stacked with a logic die that is operable to access a set of memory arrays distributed across the one or more memory dies. Such a stacked architecture may be implemented as part of a high bandwidth memory (HBM) system or a tightly-coupled dynamic random access memory (TCDRAM) system, and may support solutions for memory-centric logic, such as graphics processing units (GPUs), among other implementations. In some examples, an HBM system may include a stack of memory dies located (e.g., positioned, placed) above a logic die. In some examples, a TCDRAM system may be closely coupled (e.g., physically coupled, electrically coupled, directly coupled) with a processor, such as a GPU or other host device, as part of a physical memory map accessible to the processor. In some cases, the logic die may include multiple components such as interface blocks (e.g., memory interface blocks, interface circuitry), logic blocks, controllers, processors, and other components. A semiconductor component (e.g., a semiconductor unit, a semiconductor subsystem, a logic unit, a logic portion of an HBM system or a TCDRAM system, a heterogeneous device), such as the logic die, may be formed as a single large die with relevant circuitry, or may be formed with multiple semiconductor die portions (e.g., relatively smaller dies, dies each including a respective subset of components of a logic unit), that may be referred to as “chiplets” (e.g., logic chiplets). For example, a chiplet may include a respective portion of circuitry that may be otherwise associated with functionality of a relatively larger die.

During fabrication, a first surface (e.g., a front-side surface, a surface along a side of a substrate that had been doped for circuitry formation) of a first semiconductor component (e.g., a wafer, a reconstructed wafer including multiple chiplets forming one or more larger dies) may be bonded with a support structure, such as a wafer support system (WSS). One or more second semiconductor components (e.g., semiconductor dies) may be stacked and bonded with a second surface (e.g., back-side surface, a surface opposite a side of a substrate that had been doped for circuitry formation) of the first semiconductor component. However, a semiconductor component of a stack may be associated with one or more defects in the semiconductor component itself, or with bonding defects between semiconductor components. Such defects may compromise at least a portion of the stack of semiconductor components, which may cause the entire stack to be discarded. In some examples, a support structure may be debonded from the first semiconductor component to enable testing of one or more stacks of semiconductor components using one or more operative pads (e.g., operative contacts) at the first surface. However, the support structure may be debonded after semiconductor components have been bonded for each stack, including after an over-mold material has been deposited over the stacks and after singulation of the semiconductor components and stacks into smaller components (e.g., after the over-mold formation). Accordingly, a stack including one or more defects may still be discarded, regardless of how many semiconductor components have a successful evaluation, or at least some of the semiconductor components of a stack may be inoperable due to a defect associated with another semiconductor component. Such defects may thus result in increased component loss and wasted resources (e.g., processing time, energy) during manufacturing.

In accordance with examples as disclosed herein, a first semiconductor component (e.g., a semiconductor wafer, a reconstructed semiconductor wafer, a logic unit, a logic portion of an HBM system or a TCDRAM system, a heterogeneous device) may be formed with circuitry that enables in-situ (e.g., in-place, during manufacture) evaluation of one or more second semiconductor components (e.g., semiconductor dies), including evaluations of the second semiconductor components during various stages of stacking on the first semiconductor component. For example, a second surface (e.g., back-side surface, a surface opposite a side of a substrate of the first semiconductor device that had been doped for circuitry formation) of the first semiconductor device used to bond stacks of one or more second components may include one or more test pads to support evaluating the second semiconductor components during fabrication. For example, after a second semiconductor component (e.g., a die of a stack of dies) is bonded with the first semiconductor component (e.g., directly, via another die of the stack), a probe test may be performed by temporarily coupling a test probe with the test pads on the second surface. If a second semiconductor component has an unsuccessful evaluation (e.g., due to one or more defects), the manufacturing process may be halted for at least that stack. The stack and, in some examples, a bonded portion of the first semiconductor component, may be discarded or may be used at a lower capability (e.g., a lower storage capacity, at a lower throughput, at a lower processing power, associated with a stack of relatively fewer dies).

By supporting such evaluation during stack formation, stacks may be identified in the event of an identified defect, which may support refraining from stacking additional semiconductor components to one or more stacks associated with the defect. In some examples, such techniques may reduce semiconductor component loss (e.g., of known good dies (KGDs) that satisfy an evaluation), reduce resource consumption (e.g., time, energy), and reduce manufacturing costs. In some examples, if a defect is identified, a corresponding stack may be used to function at a lower capability that implements properly-functioning semiconductor components of a relatively shorter stack. Such processes may support stacking and testing being performed without detaching a support structure, which may support one or more evaluations being omitted or reduced after stacks are complete (e.g., before or after singulation into smaller components). In some cases, additional die testing for functionality and other purposes may be performed during or between manufacturing steps using the test pads.

In addition to applicability in memory systems as described herein, techniques for in-situ testing of stacked semiconductor components may be generally implemented to improve the sustainability of various electronic devices and systems. As the use of electronic devices has become even more widespread, the quantity of energy used and harmful emissions associated with production of electronic devices and device operation has increased. Further, the amount of waste (e.g., electronic waste) associated with disposal of electronic devices may also pose environmental concerns. Implementing the techniques described herein may improve the impact related to electronic devices by reducing materials used in production of electronic devices (e.g., due to fewer wasted dies being rejected with a whole stack) and eliminating production processes (e.g., removing evaluation steps post WSS removal), which may result in lowered production emissions, reduced electronic waste, and/or reduced energy cost, among other benefits.

Features of the disclosure are illustrated and described in the context of systems and architectures. Features of the disclosure are further illustrated and described in the context of interface architectures, semiconductor systems, illustrative fabrication techniques, semiconductor units, and flowcharts.

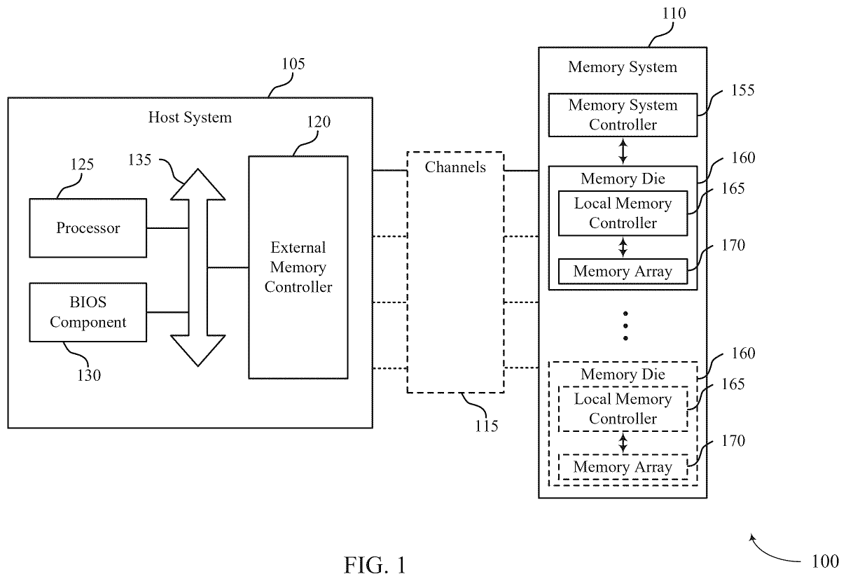

FIG. 1 shows an example of a system 100 that supports techniques for in-situ testing of stacked semiconductor components in accordance with examples as disclosed herein. The system 100 may include portions of an electronic device, such as a computing device, a mobile computing device, a wireless communications device, a graphics processing device, a vehicle, or other systems. The system 100 includes a host system 105, a memory system 110, and one or more channels 115 coupling the host system 105 with the memory system 110 (e.g., to provide a communicative coupling). The system 100 may include one or more memory systems 110, but aspects of the one or more memory systems 110 may be described in the context of a single memory system 110.

The host system 105 may be an example of a processing system (e.g., circuitry, one or more processors, an application processing system, processing circuitry, one or more processing components) that uses memory to execute processes (e.g., applications, functions, computations), such as a processing system of a computing device, a mobile computing device, a wireless communications device, a graphics processing device, a wearable device, an internet-connected device, a vehicle controller, a system on a chip (SoC), or other stationary or portable electronic device, among other examples. The host system 105 may include one or more of an external memory controller 120, a processor 125, a basic input/output system (BIOS) component 130, or other components (e.g., a peripheral component, an input/output controller, not shown). The components of the host system 105 may be coupled with one another using a bus 135.

An external memory controller 120 may be configured to enable communication of information (e.g., data, commands, control information, configuration information) between components of the system 100 (e.g., between components of the host system 105, such as the processor 125, and the memory system 110). For example, an external memory controller 120 may generate commands (e.g., in response to or to otherwise support an application of the host system 105) to write data to a memory system 110, or to read data from the memory system 110, or to otherwise communicate with a memory system 110. An external memory controller 120 may process (e.g., convert, translate) communications exchanged between the host system 105 and the memory system 110. In some examples, an external memory controller 120, or other component of the system 100, or associated functions described herein, may be implemented by or be part of the processor 125. For example, an external memory controller 120 may be hardware, firmware, or software (e.g., instructions), or some combination thereof implemented by a processor 125 or other component of the system 100 or the host system 105. Although an external memory controller 120 is illustrated outside the memory system 110, in some examples, an external memory controller 120, or its functions described herein, may be implemented by one or more components of a memory system 110 (e.g., a memory system controller 155, a local memory controller 165) or vice versa. In various examples, the host system 105 or an external memory controller 120 may be referred to as a host.

A processor 125 may be operable to provide functionality (e.g., control functionality, processing functionality) for the system 100 or the host system 105. A processor 125 may be a general-purpose processor, a digital signal processor (DSP), an application-specific integrated circuit (ASIC), a field-programmable gate array (FPGA) or other programmable logic device, discrete gate or transistor logic, discrete hardware components, or any combination thereof (e.g., as one or more processing components that are configured individually or collectively to support an application of the host system 105). In some examples, a processor 125 may be an example of a central processing unit (CPU), a graphics processing unit (GPU), a general-purpose GPU (GPGPU), or an SoC, among other examples.

In some examples, the system 100 or the host system 105 may include an input component, an output component, or a combination thereof. Input components may include a sensor, a microphone, a keyboard, another processor (e.g., on a printed circuit board), an interface (e.g., a user interface, an interface between other devices), or a peripheral that interfaces with system 100 via one or more peripheral components, among other examples. Output components may include a display, audio speakers, a printing device, another processor on a printed circuit board, or a peripheral that interfaces with the system 100 via one or more peripheral components, among other examples.

The memory system 110 may be a component of the system 100 that is operable to provide physical memory locations (e.g., addresses) that may be used or referenced by the system 100 (e.g., by the host system 105). The memory system 110 may include a memory system controller 155 and one or more memory dies 160 (e.g., memory chips) to support a capacity for data storage. The memory system 110 may be configurable to work with one or more different types of host systems 105, and may respond to and execute commands provided by the host system 105 (e.g., via an external memory controller 120). For example, the memory system 110 (e.g., a memory system controller 155) may receive a write command indicating that the memory system 110 is to store data received from the host system 105, or receive a read command indicating that the memory system 110 is to provide data stored in a memory die 160 to the host system 105, or receive a refresh command indicating that the memory system 110 is to refresh data stored in a memory die 160, among other types of commands and operations.

A memory system controller 155 may include components (e.g., circuitry, logic, instructions) operable to control operations of the memory system 110. A memory system controller 155 may include hardware, firmware, or instructions that enable the memory system 110 to perform various operations, and may be operable to receive, transmit, or execute commands, data, or control information related to operations of the memory system 110. A memory system controller 155 may be operable to communicate with one or more of an external memory controller 120, one or more memory dies 160, or a processor 125. In some examples, a memory system controller 155 may control operations of the memory system 110 in cooperation with a local memory controller 165 of a memory die 160.

Each memory die 160 may include one or more local memory controllers 165 and one or more memory arrays 170. A memory array 170 may be a collection of memory cells, with each memory cell being operable to store one or more bits of data. A memory array 170 may include a two-dimensional (2D) array of memory cells, or a three-dimensional (3D) array of memory cells. In some examples, a two-dimensional (2D) memory die 160 may include a single memory array 170. In some examples, a three-dimensional (3D) memory die 160 may include two or more memory arrays 170, which may be stacked or positioned beside one another (e.g., relative to a substrate).

A local memory controller 165 may include components (e.g., circuitry, logic, instructions) operable to control operations of a memory die 160. In some examples, a local memory controller 165 may be operable to communicate (e.g., receive or transmit data or commands or both) with a memory system controller 155. In some examples, a memory system 110 may not include a memory system controller 155, and a local memory controller 165 or an external memory controller 120 may perform various functions described herein. As such, a local memory controller 165 may be operable to communicate with a memory system controller 155, with other local memory controllers 165, or directly with an external memory controller 120, or a processor 125, or any combination thereof. Examples of components that may be included in a memory system controller 155 or a local memory controller 165 or both may include receivers for receiving signals (e.g., from the external memory controller 120), transmitters for transmitting signals (e.g., to the external memory controller 120), decoders for decoding or demodulating received signals, encoders for encoding or modulating signals to be transmitted, sense components for sensing states of memory cells of a memory array 170, write components for writing states to memory cells of a memory array 170, or various other components operable for supporting described operations of a memory system 110.

A host system 105 (e.g., an external memory controller 120) and a memory system 110 (e.g., a memory system controller 155) may communicate information (e.g., data, commands, control information, configuration information) using one or more channels 115. Each channel 115 may be an example of a transmission medium that carries information, and each channel 115 may include one or more signal paths (e.g., a transmission medium, an electrical conductor, an electrically conductive path) between terminals associated with the components of the system 100. For example, a channel 115 may be associated with a first terminal (e.g., including one or more pins, including one or more pads) at the host system 105 and a second terminal at the memory system 110. A terminal may be an example of a conductive input or output point of a device of the system 100, and a terminal may be operable to act as part of a channel 115. In some implementations, at least the channels 115 between a host system 105 and a memory system 110 may include or be referred to as a host interface (e.g., a physical host interface). In some implementations, a host interface may include or be associated with interface circuitry (e.g., signal drivers, signal latches) at the host system 105 (e.g., at an external memory controller 120), or at the memory system 110 (e.g., at a memory system controller 155), or both.

In some examples, a channel 115 (e.g., associated signal paths and terminals) may be dedicated to communicating one or more types of information. For example, the channels 115 may include one or more command and address channels, one or more clock signal channels, one or more data channels, among other channels or combinations thereof. In some examples, signaling may be communicated via the channels 115 using single data rate (SDR) signaling or double data rate (DDR) signaling. In SDR signaling, one modulation symbol (e.g., signal level) of a signal may be registered for each clock cycle (e.g., on a rising or falling edge of a clock signal). In DDR signaling, two modulation symbols of a signal may be registered for each clock cycle (e.g., on both a rising edge and a falling edge of a clock signal).

In some examples, at least a portion of the system 100 may implement a stacked die architecture in which multiple semiconductor dies are physically and communicatively coupled. In some such implementations, circuitry for accessing one or more memory arrays 170 (e.g., circuitry of a memory system 110) may be distributed among multiple semiconductor dies of a stack (e.g., a stack of multiple directly-coupled semiconductor dies). For example, a first die may include a set of multiple first interface blocks (e.g., memory interface blocks, instances of first interface circuitry) and one or more second dies may include corresponding second interface blocks, each coupled with a first interface block of the first die, that are each configured to access one or more memory arrays of the second dies. In some examples, the system may include a controller (e.g., a memory controller, an interface controller, a host interface controller, at least a portion of an external memory controller 120) for each set of one or more first interface blocks to support access operations (e.g., to access one or more memory arrays 170) via the set of first interface blocks. In some examples, such controllers may be located in the same first die as the first interface blocks.

In some examples, multiple semiconductor dies of a memory system 110 or of a system 100 (e.g., an HBM system including aspects of a memory system 110, or a TCDRAM system including aspects of a memory system 110 and a host system 105) may include one or more array dies (e.g., memory dies 160) stacked with a logic die (e.g., that includes aspects of the host system 105, that is coupled with another die that includes the host system 105) that includes interface blocks operable to access a set of memory arrays 170 distributed across the one or more second dies. A system 100 or portion thereof having a stacked memory architecture may support techniques for semiconductor die coupling in stacked memory architectures. For instance, a semiconductor unit (e.g., a semiconductor component, a logic unit) may be formed with multiple semiconductor die portions (e.g., chiplets, logic chiplets) that are interconnected after an evaluation procedure (e.g., as an interconnection of logic chiplets, such as KGDs, that satisfy the evaluation). At least some of the chiplets may be further coupled with one or more stacked memory arrays 170, which also may have dedicated vias for power delivery (e.g., PDN TRVs).

In some examples, a first semiconductor component (a semiconductor wafer, a reconstructed semiconductor wafer, a logic unit, a logic portion of an HBM system or a TCDRAM system, a heterogeneous device) may include circuitry that supports in-situ testing of one or more second semiconductor components (e.g., array dies, memory dies 160). For example, at least during fabrication, a first semiconductor component may include one or more test pads to support evaluating the one or more second semiconductor components that are coupled with (e.g., bonded with) the first semiconductor component during fabrication. For example, a probe test may be performed by temporarily coupling a test probe with the test pads. If a second semiconductor component has an unsuccessful evaluation (e.g., due to one or more defects), the manufacturing process may be halted for at least that stack. Such test pads may thus reduce die loss as well as energy consumption and resource use by allowing testing of dies during manufacturing and avoiding further testing after separating from a support structure.

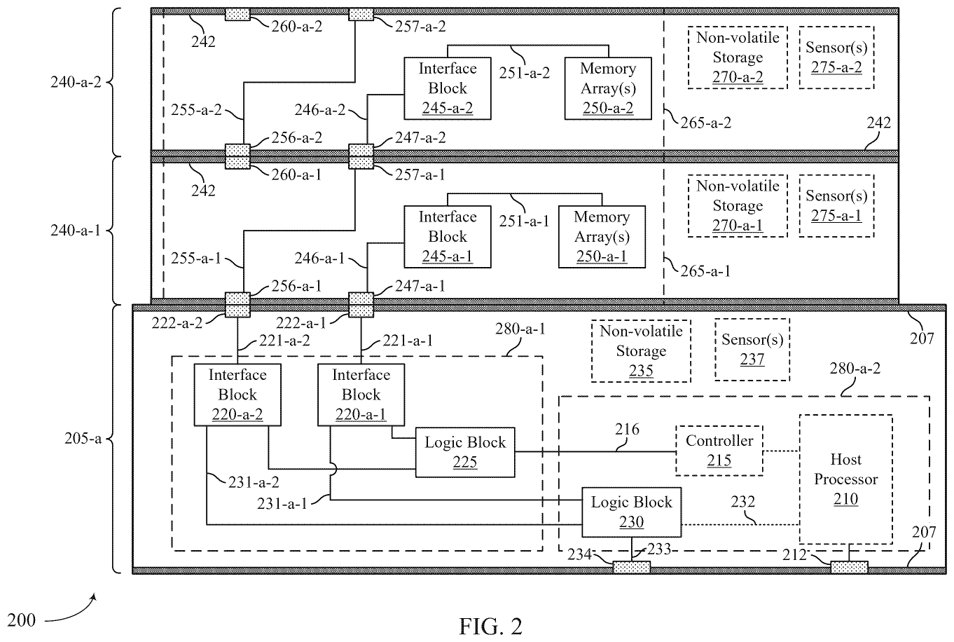

FIG. 2 shows an example of a system 200 (e.g., a semiconductor system, a system of coupled semiconductor dies, an HBM system, a TCDRAM system) that supports techniques for in-situ testing of stacked semiconductor components in accordance with examples as disclosed herein. The system 200 illustrates an example of a die 205 (e.g., a die 205-a, a semiconductor die, a logic die, a processor die, a host die, a logic unit) that is coupled with one or more dies 240 (e.g., dies 240-a-1 and 240-a-2, semiconductor dies, memory dies, array dies, memory units). A die 205 or a die 240 may be formed using a respective semiconductor substrate (e.g., a substrate of crystalline semiconductor material such as silicon, germanium, silicon-germanium, gallium arsenide, or gallium nitride), or a silicon-on-insulator (SOI) substrate (e.g., silicon-on-glass (SOG), silicon-on-sapphire (SOS)), or epitaxial semiconductor materials formed on another substrate, among other examples. Although the illustrated example of a system 200 includes two dies 240, a system 200 in accordance with the described techniques may include any quantity of one or more dies 240 coupled with a die 205, among other dies of a stack or other coupled layout. Further, although non-limiting examples of the system 200 herein are generally described in terms of applicability to memory systems, memory sub-systems, memory devices, or a combination thereof, examples of the system 200 are not so limited. For example, aspects of the present disclosure may be applied as well to any computing system, computing sub-system, processing system, processing sub-system, component, device, structure, or other types of systems or sub-systems used for applications such as data collecting, data processing, data storage, networking, communication, power, artificial intelligence, system-on-a-chip, control, telemetry, sensing and monitoring, digital entertainment, or any combination thereof.

The system 200 illustrates an example of interface circuitry between a host and memory (e.g., via a host interface, via a physical host interface) that is implemented in (e.g., divided between) multiple semiconductor dies (e.g., a stack of directly-coupled dies). For example, the die 205-a may include a set of one or more interface blocks 220 (e.g., interface blocks 220-a-1 and 220-a-2, memory interface blocks), and each die 240 may include a set of one or more interface blocks 245 (e.g., access interface blocks) and one or more memory arrays 250 (e.g., die 240-a-1 including an interface block 245-a-1 coupled with a set of one or more memory arrays 250-a-1, die 240-a-2 including an interface block 245-a-2 coupled with a set of one or more memory arrays 250-a-2). The memory arrays 250 may be examples of memory arrays 170, and may include memory cells of various architectures, such as RAM, DRAM, SDRAM, SRAM, FeRAM, MRAM, RRAM, PCM, chalcogenide, NOR, or NAND memory cells, or any combination thereof.

Although the example of system 200 is illustrated with one interface block 245 included in each die 240, a die 240 in accordance with the described techniques may include any quantity of one or more interface blocks 245, each coupled with a respective set of one or more memory arrays 250, and each coupled with an interface block 220 of a die 205. Thus, the interface circuitry of a system 200 may include one or more interface blocks 220 of a die 205, with each interface block 220 being coupled with (e.g., in communication with) one or more interfaces block 245 of a die 240 (e.g., external to the die 205). In some examples, a coupled combination of an interface block 220 and an interface block 245 (e.g., coupled via a bus associated with one or more channels, such as one or more data channels, one or more control channels, one or more clock channels, one or more pseudo-channels, or a combination thereof) may include or be referred to as a data path associated with a respective set of one or more memory arrays 250.

In some implementations (e.g., TCDRAM implementations), a die 205 may include a host processor 210. A host processor 210 may be an example of a host system 105, or a portion thereof (e.g., a processor 125, aspects of an external memory controller 120, or both). The host processor 210 may be configured to perform operations that implement storage of the memory arrays 250 (e.g., to support an application or other function of a host system 105, which may request access of the memory arrays 250). For example, the host processor 210 may receive data read from the memory arrays 250, or may transmit data to be written to the memory arrays 250, or both (e.g., in accordance with an application or other operations of the host processor 210). Additionally, or alternatively, a host processor 210 may be external to a die 205 (e.g., in HBM implementations), such as in another semiconductor die or other component that is coupled with (e.g., communicatively coupled with, directly coupled with, bonded with, coupled via another intervening component) the die 205 via one or more contacts 212 (e.g., externally-accessible terminals of the die 205).

A host processor 210 may be configured to communicate (e.g., transmit, receive) signaling with interface blocks 220 via a host interface 216 (e.g., a physical host interface), which may implement aspects of channels 115 described with reference to FIG. 1. In some examples, a host interface 216 may provide a communicative coupling between physical or functional boundaries of a host system 105 and a memory system 110. For example, the host processor 210 may be configured to communicate access signaling (e.g., control signaling, access command signaling, data signaling, configuration signaling) via a host interface 216 to support access operations (e.g., read operations, write operations) on the memory arrays 250, among other operations. Although the example of system 200 includes a single host interface 216, a system in accordance with the described techniques may include any quantity of one or more host interfaces 216 for accessing memory arrays 250 of the system.

In some examples, a respective host interface 216 may be coupled between a set of one or more interface blocks 220 (e.g., interface blocks 220-a-1 and 220-a-2) and a respective controller 215. A controller 215 may be an example of control circuitry (e.g., memory controller circuitry, host interface control circuitry) associated with a host system 105, and may be associated with implementing respective instances of one or more aspects of an external memory controller 120, or of a memory system controller 155, or a combination thereof. For example, the controller 215 may be operable to respond to indications (e.g., requests, commands) from the host processor 210 to access one or more memory arrays 250 in support of a function or application of the host processor 210, to transmit associated commands (e.g., for one or more interface blocks 220) to access the one or more memory arrays 250, and to communicate data (e.g., write data, read data) with the host processor 210, among other functions.

In some examples, one or more controllers 215 may be implemented in a die 205 (e.g., the same die that includes one or more interface blocks 220) whether a host processor 210 is included in the die 205, or is external to the die 205. In some other examples, controllers 215 or associated circuitry or functionality may be implemented external to a die 205 (e.g., in another die, not shown, coupled with respective interface blocks 220 via respective terminals for each of the respective host interfaces 216), which may be in the same die as or a different die from a die that includes a host processor 210. An interface block 220 may be operable via a single controller 215, or by one or more of a set of multiple controllers 215 (e.g., in accordance with a controller multiplexing scheme). In some other examples, aspects of one or more controllers 215 may be included in the host processor 210 (e.g., as a memory interface of the host processor 210, as a memory interface of a host system 105).

Although, in some examples, a controller 215 may be directly coupled with one or more interface blocks 220 (not shown), in some other examples, a controller 215 (e.g., a host interface 216) may be coupled with a set of multiple interface blocks 220 via a logic block 225 (e.g., logic circuitry for a channel set, logic circuitry for a host interface 216, multiplexing circuitry). For example, the logic block 225 may be coupled with the interface block 220-a-1 via a bus 223-a-1 and coupled with the interface block 220-a-2 via a bus 223-a-1. A controller 215 and one or more corresponding interface blocks 220 and may communicate (e.g., collaborate) using the host interface 216 via a logic block 225 to perform one or more operations (e.g., scheduling operations, access operations, operations initiated by a host processor 210) associated with accessing a corresponding set of one or more memory arrays 250.

In some examples, a logic block 225, a controller 215, or a host interface 216, or a combination thereof may be associated with a “channel set” that corresponds to multiple memory arrays 250 (e.g., for parallel or otherwise coordinated access of the multiple memory arrays 250). For example, such a channel set may be associated with multiple memory arrays 250 accessed via a single interface block 245, or multiple memory arrays 250 each accessed via a respective one of the interface blocks 245, or multiple memory arrays 250 each accessed via a respective one of the interface blocks 220, any of which may be associated with signaling via a single logic block 225, via a single host interface 216, or via a single controller 215. These and other configurations for implementing one or more channel sets in a system may support various techniques for parallelism and high bandwidth data transfer, memory management operations, repair and replacement techniques, or power and thermal distribution, among other techniques that leverage the described coupling of components and interfaces among multiple semiconductor dies (e.g., in accordance with a high bandwidth memory configuration of the system 200, in accordance with a tightly-coupled configuration of the system 200). In some examples, such techniques may be implemented (e.g., at or using a logic block 225) in a manner that is transparent to the host interface 216 or other aspects of a host system 105.

In some examples, a host interface 216 may include a respective set of one or more signal paths for each logic block 225 or interface block 220, such that the host processor 210 may communicate with each logic block 225 or interface block 220 via its corresponding set of signal paths (e.g., in accordance with a selection of the corresponding set to perform access operations via a logic block 225 or interface block 220 that is selected by the host processor 210). Additionally, or alternatively, a host interface 216 may include one or more signal paths that are shared among multiple logic blocks 225 (not shown) or interface blocks 220, and a logic block 225, an interface block 220, or a host processor 210, or any of these may interpret, ignore, respond to, or inhibit response to signaling via shared signal paths of the host interface 216 based on a logical indication (e.g., an addressing indication associated with the logic block 225 or interface block 220, an interface enable signal, or an interface select signal, which may be provided by the host processor 210, the corresponding logic block 225, or the corresponding interface block 220 depending on signaling direction).

In some examples, a host processor 210 may determine to access an address (e.g., a logical address of a memory array 250, a physical address of a memory array 250, an address of a logic block 225, an address of an interface block 220, an address of a host interface 216, in response to an application of or supported by the host processor 210), and determine which controller 215 to transmit access signaling to for accessing the address (e.g., a controller 215, logic block 225, or interface block 220 corresponding to the address). In some examples, the address may be associated with a row of memory cells of the memory array 250, a column of memory cells of the memory array 250, or both. The host processor 210 may transmit access signaling (e.g., one or more access signals, one or more access commands) to the determined controller 215 and, in turn, the determined controller 215 may transmit access signaling to the corresponding logic block 225 or interface block 220. The corresponding interface block 220 may subsequently transmit access signaling to the coupled interface block 245 to access the determined address (e.g., of a corresponding memory array 250).

A die 205 may also include a logic block 230 (e.g., a shared logic block, a central logic block, common logic circuitry, evaluation circuitry, memory system configuration circuitry, memory system management circuitry), which may be configured to communicate (e.g., transmit, receive) signaling with the logic blocks 225, the interface blocks 220, or both of the die 205. In some cases, a logic block 230 may be configured to communicate information (e.g., commands, instructions, indications, data) with one or more logic blocks 225 or interface blocks 220 to facilitate operations of the system 200. For example, a logic block 230 may be configured to transmit configuration signaling (e.g., initialization signaling, evaluation signaling, mapping signaling), which may be received by logic blocks 225 or interface blocks 220 to support configuration of the logic blocks 225 or interface blocks 220, or other aspects of operating the dies 240 (e.g., via the respective interface blocks 245). A logic block 230 may be coupled with each logic block 225 and each interface block 220 via a respective bus. In some examples, such buses may each include a respective set of one or more signal paths, such that a logic block 230 may communicate with each logic block 225 or each interface block 220 via the respective set of signal paths. Additionally, or alternatively, such buses may include one or more signal paths that are shared among multiple logic blocks 225 or interface blocks 220 (not shown).

In some implementations, a logic block 230 may be configured to communicate (e.g., transmit, receive) signaling with a host processor 210 (e.g., via a bus, via a contact 212 for a host processor 210 external to a die 205) such that the logic block 230 may support an interface between the host processor 210 and the logic blocks 225 or interface blocks 220. For example, a host processor 210 may be configured to transmit initialization signaling (e.g., boot commands), or other configuration or operational signaling, which may be received by a logic block 230 to support initialization, configuration, evaluation, or other operations of the logic blocks 225 or interface blocks 220. Additionally, or alternatively, in some implementations, a logic block 230 may be configured to communicate (e.g., transmit, receive) signaling with a component outside the system 200 (e.g., via a contact 234, which may be an externally-accessible terminal of the die 205), such that the logic block 230 may support an interface that bypasses a host processor 210. Additionally, or alternatively, a logic block 230 may communicate with a host processor 210, and may communicate with one or more memory arrays 250 of one or more dies 240 (e.g., to perform self-test operations for access of memory arrays 250). In some examples, such implementations may support evaluations, configurations, or other operations of the system 200, via one or more contacts 234 that are accessible at a physical interface of the system, during manufacturing, assembly, validation, or other operation associated with the system 200 (e.g., before coupling with a host processor 210, without implementing a host processor 210, for operations independent of a host processor). Additionally, or alternatively, a logic block 230 may implement one or more aspects of a controller 215. For example, a logic block 230 may include or operate as one or more controllers 215 and may perform operations ascribed to a controller 215.

Each interface block 220 may be coupled with at least a respective bus 221 of the die 205, and a respective bus 246 of a die 240, that are configured to communicate signaling with a corresponding interface block 245 (e.g., via one or more associated signal paths). For example, the interface block 220-a-1 may be coupled with the interface block 245-a-1 via a bus 221-a-1 and a bus 246-a-1, and the interface block 220-a-2 may be coupled with the interface block 245-a-2 via a bus 221-a-2 and a bus 246-a-2. In some examples, a die 240 may include a bus that bypasses operational circuitry of the die 240 (e.g., that bypasses interface blocks 245 of a given die 240), such as a bus 255. For example, the interface block 220-a-2 may be coupled with the interface block 245-a-2 of the die 240-a-2 via a bus 255-a-1 of the die 240-a-1, which may bypass interface blocks 245 of the die 240-a-1. Such techniques may be extended for interconnection among more than two dies 240 (e.g., for interconnection via a respective bus 255 of multiple dies 240).

The respective signal paths of buses 221, 246, and 255 may be coupled with one another, from one die to another, via various arrangements of contacts at the surfaces of interfacing dies (e.g., exposed contacts, metal surfaces of the respective dies). For example, the bus 221-a-1 may be coupled with the bus 246-a-1 via a contact 222-a-1 of (e.g., at a surface of) the die 205-a and a contact 247-a-1 of the die 240-a-1, the bus 221-a-2 may be coupled with the bus 255-a-1 via a contact 222-a-2 of the die 205 and a contact 256-a-1 of the die 240-a-1, the bus 255-a-1 may be coupled with the bus 246-a-2 via a contact 257-a-1 of the die 240-a-1 and a contact 247-a-2 of the die 240-a-2, and so on. Although each respective bus is illustrated with a single line, coupled via singular contacts, it is to be understood that each signal path of a given bus may be associated with respective contacts to support a separate communicative coupling via each signal path of the given bus. In some examples, a bus 255 may traverse a portion of a die 240 (e.g., in an in-plane direction, along a direction different from a thickness direction, in a waterfall arrangement, in a staircase arrangement), which may support an arrangement of contacts 222 along a surface of a die 205, among other contacts, being coupled with interface blocks 245 of different dies 240 along a stack direction (e.g., via respective contacts 256 and 257 that are non-overlapping when viewed along a thickness direction).

The interconnection of interfacing contacts may be supported by various techniques. For example, in a hybrid bonding implementation, interfacing contacts may be coupled by a fusion of conductive materials (e.g., electrically conductive materials) of the interfacing contacts (e.g., without solder or other intervening material between contacts). For example, in an assembled condition, the coupling of the die 205-a with the die 240-a-1 may include a conductive material of the contact 222-a-2 being fused with a conductive material of the contact 256-a-1, and the coupling of the die 240-a-1 with the die 240-a-2 may include a conductive material of the contact 257-a-1 being fused with a conductive material of the contact 247-a-2, and so on. In some examples, such coupling may include an inoperative fusion of contacts (e.g., a non-communicative coupling, a physical coupling), such as a fusion of the contact 260-a-1 with the contact 256-a-2, neither of which are coupled with operative circuitry of the dies 240-a-1 or 240-a-2. In some examples, such techniques may be implemented to improve coupling strength or uniformity (e.g., implementing contacts 260, which may not be operatively coupled with an interface block 245 or an interface block 220), or such a coupling may be a byproduct of a repetition of components that, in various configurations, may be operative or inoperative. (e.g., where, for dies 240 with a common arrangement of contacts 256 and 257, contacts 256-a-1 and 257-a-1 provide a communicative path between the interface block 245-a-2 and the interface block 220-a-2, but the contacts 256-a-2 and 257-a-2 do not provide a communicative path between an interface block 245 and an interface block 220).

In some examples, a fusion of conductive materials between dies (e.g., between contacts) may be accompanied by a fusion of other materials at one or more surfaces of the interfacing dies. For example, in an assembled condition, the coupling of the die 205 with the die 240-a-1 may include a dielectric material 207 (e.g., an electrically non-conductive material) of the die 205-a being fused with a dielectric material 242 of the die 240-a-1, and the coupling of the die 240-a-1 with the die 240-a-2 may include a dielectric material 242 of the die 240-a-1 being fused with a dielectric material 242 of the die 240-a-2. In some examples, such dielectric materials may include an oxide, a nitride, a carbide, an oxide-nitride, an oxide-carbide, or other conversion or doping of a substrate material (e.g., a semiconductor substrate material) of the die 205 or dies 240, among other materials that may support such fusion. However, coupling among dies 205 and dies 240 may be implemented in accordance with other techniques, which may implement solder, adhesives, thermal interface materials, and other intervening materials.

In some examples, dies 240 may be coupled in a stack (e.g., forming a “cube” or other arrangement of dies 240), and one or more of such stacks may subsequently be coupled with a die 205 (e.g., in a stack-to-chip bonding arrangement). In some examples, respective set(s) of one or more dies 240 may be coupled with each die 205 of multiple dies 205 as formed in a wafer (e.g., in a chip-to-wafer bonding arrangement, in a stack-to-wafer bonding arrangement, before cutting the wafer of dies 205), and the dies 205 of the wafer, each coupled with their respective set(s) of dies 240, may be separated from one another (e.g., by cutting at least the wafer of dies 205). In some other examples, respective set(s) of one or more dies 240 may be coupled with a respective die 205 after the die 205 is separated from a wafer of dies 205 (e.g., in a chip-to-chip bonding arrangement). In some other examples, a respective set of one or more wafers, each including multiple dies 240, may be coupled in a stack (e.g., in a wafer-to-wafer bonding arrangement). In various examples, such techniques may be followed by separating stacks of dies 240 from the coupled wafers, or the stack of wafers having dies 240 may be coupled with another wafer including multiple dies 205 (e.g., in a second wafer-to-wafer bonding arrangement), which may be followed by separating systems 200 from the coupled wafers. In some other examples, wafer-to-wafer coupling techniques may be implemented by stacking one or more wafers of dies 240 (e.g., sequentially) over a wafer of dies 205 before separation into systems 200, among other examples for forming systems 200.

The buses 221, 246, and 255 may be implemented to provide a configured signaling (e.g., a coordinated signaling, a logical signaling, modulated signaling, digital signaling) between an interface block 220 and a corresponding interface block 245, which may involve various modulation or encoding techniques by a transmitting interface block (e.g., via a driver component of the transmitting interface block). In some examples, such signaling may be supported by (e.g., accompanied by) clock signaling communicated via the respective buses (e.g., in coordination with signal transmission). For example, the buses may be configured to convey one or more clock signals transmitted by the interface block 220 for reception by the interface block 245 (e.g., to trigger signal reception by a latch or other reception component of the interface block 245, to support clocked operations of the interface block 245). Additionally, or alternatively, the buses may be configured to convey one or more clock signals transmitted by the interface block 245 for reception by the interface block 220 (e.g., to trigger signal reception by a latch or other reception component of the interface block 220, to support clocked operations of the interface block 220). Such clock signals may be associated with the communication (e.g., unidirectional communication, bidirectional communication, deterministic communication) of various signaling, such as control signaling, command signaling, data signaling, or any combination thereof. For example, the buses may include one or more signal paths for communications of a data bus (e.g., one or more data channels, a DQ bus, via a data interface of the interface blocks) in accordance with one or more corresponding clock signals (e.g., data clock signals), or one or more signal paths for communications of a control bus (e.g., a command/address (C/A) bus, via a command interface of the interface blocks) in accordance with one or more clock signals (e.g., control clock signals), or any combination thereof.

Interface blocks 220, interface blocks 245, logic blocks 225, and a logic block 230 each may include circuitry (signaling circuitry, multiplexing circuitry, processing circuitry, controller circuitry, logic circuitry, physical components, hardware) in various configurations (e.g., hardware configurations, logic configurations, software or instruction configurations) that support the functionality allocated to the respective block for accessing or otherwise operating a corresponding set of memory arrays 250. For example, interface blocks 220 may include circuitry configured to perform a first subset of operations that support access of the memory arrays 250, and interface blocks 245 may include circuitry configured to perform a second subset of operations that support access of the memory arrays 250. In some examples, the interface blocks 220, the interface blocks 245, and logic blocks 225 may support a functional split or distribution of functionality associated with a memory system controller 155, a local memory controller 165, or both across multiple dies (e.g., a die 205 and at least one die 240). In some implementations, a logic block 230 may be configured to coordinate or configure aspects of the operations of the interface blocks 220, of the interface blocks 245, of the logic blocks 225, or a combination thereof, and may support implementing one or more aspects of a memory system controller 155. Such operations, or subsets of operations, may include operations performed in response to commands from the host processor 210 or a controller 215, or operations performed without commands from a host processor 210 or a controller 215 (e.g., operations determined by or initiated by a logic block 225, operations determined by or initiated by an interface block 220, operations determined by or initiated by an interface block 245, operations determined by or initiated by a logic block 230), or various combinations thereof.

In some implementations, the system 200 may include one or more instances of non-volatile storage (e.g., non-volatile storage 235 of a die 205, non-volatile storage 270 of one or more dies 240, or a combination thereof). In some examples, a logic block 230, logic blocks 225, interface blocks 220, interface blocks 245, or a combination thereof may be configured to communicate signaling with one or more instances of non-volatile storage. For example, a logic block 230, logic blocks 225, interface blocks 220, or interface blocks 245 may be coupled with one or more instances of non-volatile storage via one or more buses (not shown), or respective contacts (not shown), where applicable, which may each include one or more signal paths operable to communicate signaling (e.g., command signaling, data signaling). In some examples, a logic block 230, one or more logic blocks 225, one or more interface blocks 220, one or more interface blocks 245, or a combination thereof may configure one or more operations based on information (e.g., instructions, configurations, parameters) stored in one or more instances of non-volatile storage. Additionally, or alternatively, in some examples, a logic block 230, one or more logic blocks 225, one or more interface blocks 220, one or more interface blocks 245, or a combination thereof may write information (e.g., configuration information, evaluation information) to be stored in one or more instances of non-volatile storage. In some examples, such non-volatile storage may include fuses, antifuses, or other types of one-time programmable storage elements, or any combination thereof.

In some implementations, the system 200 may include one or more sensors (e.g., one or more sensors 237 of a die 205, one or more sensors 275 of one or more dies 240, or a combination thereof). In some implementations, a logic block 230, logic blocks 225, interface blocks 220, interface blocks 245, or a combination thereof may be configured to receive one or more indications based on measurements of one or more sensors of the system 200. For example, a logic block 230, logic blocks 225, interface blocks 220, or interface blocks 245 may be coupled with one or more sensors via one or more buses (not shown), or respective contacts (not shown). Such sensors may include temperature sensors, current sensors, voltage sensors, counters, and other types of sensors. In some examples, a logic block 230, one or more logic blocks 225, one or more interface blocks 220, one or more interface blocks 245, or a combination thereof may configure one or more operations based on output of the one or more sensors. For example, a logic block 230 may configure one or more operations of logic blocks 225 or interface blocks 220 based on signaling (e.g., indications, data) received from the one or more sensors. Additionally, or alternatively, a logic block 225 or an interface block 220 may generate access signaling for transmitting to a corresponding interface block 245 based on one or more sensors.

In some examples, circuitry of logic blocks 225, interface blocks 220, interface blocks 245, or a logic block 230, or any combination thereof may include components (e.g., transistors) formed at least in part from doped portions of a substrate of the respective die. In some examples, a substrate of a die 205 may have characteristics (e.g., materials, material characteristics, physical shapes or dimensions) that are different from those of a substrate of a die 240. Additionally, or alternatively, in some examples, transistors formed from a substrate of a die 205 may have characteristics (e.g., manufacturing characteristics, performance characteristics, physical shapes or dimensions) that are different from transistors formed from a substrate of a die 240 (e.g., in accordance with different transistor architectures, in accordance with different transistor designs).

In some examples, the interface blocks 220 may support a layout for one or more components within the interface blocks 220. For example, the layout may include pairing components to share an access port (e.g., a command port, a data port). Further, in some examples, the layout may support interfaces for a controller 215 (e.g., a host interface 216) that are different from interfaces for an interface block 245 (e.g., via the buses 221). For instance, a host interface 216 may be synchronous and have separate channels for read and write operations, while an interface between an interface block 220 and one or more interface blocks 245 may be asynchronous and support both read and write operations with the same channel. In some examples, signaling of a host interface 216 may be implemented with a deterministic timing (e.g., deterministic between a controller 215 and a logic block 225 or one or more interface blocks 220), which may be associated with a configured timing between a first signal and a responsive second signal. In some examples, signaling between an interface block 220 and one or more interface blocks 245 may be implemented with a timing that is different from timing of a host interface 216 (e.g., in accordance with a different clock frequency, in accordance with a timing offset, such as a phase offset), which may be deterministic or non-deterministic.

A die 240 may include one or more units 265 (e.g., modules) that are separated from a semiconductor wafer having a pattern (e.g., a two-dimensional pattern) of units 265. Although each die 240 of the system 200 is illustrated with a single unit 265 (e.g., unit 265-a-1 of die 240-a-1, unit 265-a-2 of die 240-a-2), a die 240 in accordance with the described techniques may include any quantity of units 265, which may be arranged in various patterns (e.g., sets of one or more units 265 along a row direction, sets of one or more units 265 along a column direction, among other patterns). Each unit 265 may include at least the circuitry of a respective interface block 245, along with memory array(s) 250, a bus 251, a bus 246, and one or more contacts 247 corresponding to the respective interface block 245. In some examples, where applicable, each unit 265 may also include one or more buses 255, contacts 256, contacts 257, or contacts 260 (e.g., associated with a respective interface block 245 of a unit 265 of a different die 240), which may support various degrees of stackability or modularity among or via units 265 of other dies 240. Although examples of non-volatile storage 270 and sensors 275 are illustrated outside units 265, in some other examples, non-volatile storage 270, sensors 275, or both may additionally, or alternatively, be included in units 265.

In some examples, the interface blocks 220 may include circuitry configured to receive first access command signaling (e.g., from a host processor 210, from a controller 215, from a logic block 225, via a host interface 216, via one or more contacts 212 from a host processor 210 or controller 215 external to a die 205, based on a request from a host application), and to transmit second access command signaling to the respective (e.g., coupled) interface block 245 based on (e.g., in response to) the received first access command signaling. The interface blocks 245 may accordingly include circuitry configured to receive the second access command signaling from the respective interface block 220 and, in some examples, to access a respective set of one or more memory arrays 250 based on (e.g., in response to) the received second access command signaling. In various examples, the first access command signaling may include access commands that are associated with a type of operation (e.g., a read operation, a write operation, a refresh operation, a memory management operation), which may be associated with an indication of an address of the one or more memory arrays 250 (e.g., a logical address, a physical address). In some examples, the first access command signaling may include an indication of a logical address associated with the memory arrays 250, and circuitry of an interface block 220 may be configured to generate the second access command signaling to indicate a physical address associated with the memory arrays 250 (e.g., a row address, a column address, using a logical-to-physical (L2P) table or other mapping or calculation functionality of the interface block 220).

In some examples, to support write operations of the system 200, circuitry of the interface blocks 220 may be configured to receive (e.g., from a host processor 210, from a controller 215, from a logic block 225) first data signaling associated with the first access command signaling, and to transmit second data signaling (e.g., associated with second access command signaling) based on received first access command signaling and first data signaling. The interface blocks 245 may accordingly be configured to receive second data signaling, and to write data to one or more memory arrays 250 (e.g., in accordance with an indicated address associated with the first access command signaling) based on the received second access command signaling and second data signaling. In some examples, the interface blocks 220 may include an error control functionality (e.g., error detection circuitry, error correction circuitry, error correction code (ECC) logic, an ECC engine) that supports the interface blocks 220 generating the second data signaling based on performing an error control operation using the received first data signaling (e.g., detecting or correcting an error in the first data signaling, determining one or more parity bits to be conveyed in the second data signaling and written with the data).

In some examples, to support read operations of the system 200, circuitry of the interface blocks 245 may be configured to read data from the memory arrays 250 based on received second access command signaling, and to transmit first data signaling based on the read data. The interface blocks 220 may accordingly be configured to receive first data signaling, and to transmit second data signaling (e.g., to a host processor 210, to a controller 215, to a logic block 225) based on the received first data signaling. In some examples, the interface blocks 220 may include an error control functionality that supports the interface blocks 220 generating the second data signaling based on performing an error control operation using the received first data signaling (e.g., detecting or correcting an error in the first data signaling, which may include a calculation involving one or more parity bits received with the first data signaling).

In some examples, access command signaling that is transmitted to the interface blocks 245, among other signaling, may be generated (e.g., based on access command signaling received from a host processor 210, based on initiation signaling received from a host processor 210, without receiving or otherwise independent from signaling from a host processor 210) in accordance with various determination or generation techniques configured at the interface blocks 220 or the logic blocks 225 (e.g., based on a configuration for accessing memory arrays 250 that is modified at the interface blocks 220 or the logic blocks 225). In some examples, such techniques may involve signaling or other coordination with a logic block 230, a logic block 225, a host processor 210, one or more controllers 215, one or more instances of non-volatile storage, one or more sensors, or any combination thereof. Such techniques may support the interface blocks 220 or logic blocks 225 configuring aspects of the access operations performed on the memory arrays 250 by a respective interface block 245, among other operations. For example, interface blocks 220 or logic blocks 225 may include evaluation circuitry, access configuration circuitry, signaling circuitry, scheduling circuitry, repair circuitry, refresh circuitry, error control circuitry, adverse access (e.g., row hammer) mitigation circuitry, and other circuitry operable to configure operations associated with one or more dies (e.g., operations associated with accessing memory arrays 250 of the dies 240).

In some examples, functionality of a die 205 may be implemented as a semiconductor unit (e.g., a semiconductor system) that is formed with multiple semiconductor die portions (e.g., semiconductor chiplets, relatively smaller semiconductor dies, KGDs), where each die portion may include respective portions of circuitry associated with the die 205. For example, a unit 280 may represent a portion of the circuitry components included in a die portion (e.g., in a chiplet), and the die portion may include an integer multiple of units 280. In some examples, each semiconductor die portion of a semiconductor unit may include different respective portions of circuitry. As a non-limiting example, a semiconductor unit (e.g., having the functionality of a die 205) may be formed by one or more first die portions having one or more units 280-a-1 and one or more second die portions having one or more units 280-a-2. The one or more units 280-a-1 may include one or more interface blocks 220, a logic block 225, or any combination thereof, and the one or more units 280-a-2 may include a host processor 210, one or more controllers 215, a logic block 230, or any combination thereof. Although non-limiting examples of units 280 are shown, each unit 280 may include any combination of components of a die 205, or other components. For example, a unit 280-a-1 may additionally include a logic block 230, or a logic block 225 may be included in a different unit 280 (e.g., of another chiplet, in a divided HBM or TCDRAM implementation). In some examples, a respective set of one or more dies 240 may be stacked on a corresponding die portion (e.g., a die portion having one or more units 280-a-1), and the corresponding die portion may include circuitry to operate (e.g., control) the respective set of one or more dies 240 (e.g., a unit 280-a-1 may correspond to one or more units 265 of each die 240 in the respective set).

In accordance with examples disclosed herein, a first semiconductor component, such as a logic wafer (e.g., a wafer including a set of one or more dies 205, such as before singulation, a portion of an interface wafer, reconstructed wafer made of chiplets) may include circuitry that supports in-situ testing of one or more second semiconductor components (e.g., dies 240, during stacking operations). For example, a wafer including one or more dies 205 may include one or more test pads (e.g., additional contacts) along a same surface (e.g., a back-side surface, a surface opposite a side of a substrate that had been doped for circuitry formation, a surface including contacts 222) that is used to bond stacks of one or more dies 240, where such test pads may be outside the bonding area of the dies 240. The test pads may be coupled with at least a portion of the circuitry of the dies 205 (e.g., interface blocks 220, logic blocks 225, controller 215, logic blocks 230, host processors 210, among other circuitry) as well as with one or more conductors. The conductors may be coupled with the circuitry of the dies 205, as well as with one or more operative pads (e.g., contacts 234, contacts 212). The one or more conductors may be examples of or include the host interface 216, buses 231, buses 232, buses 233, or other conductive signal paths described herein. In some examples, the one or more conductors may be formed concurrently with one or more other conductors, including through-silicon vias (TSVs), power distribution network (PDN) through reconstruction vias (TRVs) (e.g., that may be for power delivery of one or more dies 240 and may bypass one or more chiplets or a larger die of a logic layer), various wiring, among other conductors, as part of a manufacturing process for a semiconductor system (e.g., a system of stacked dies).

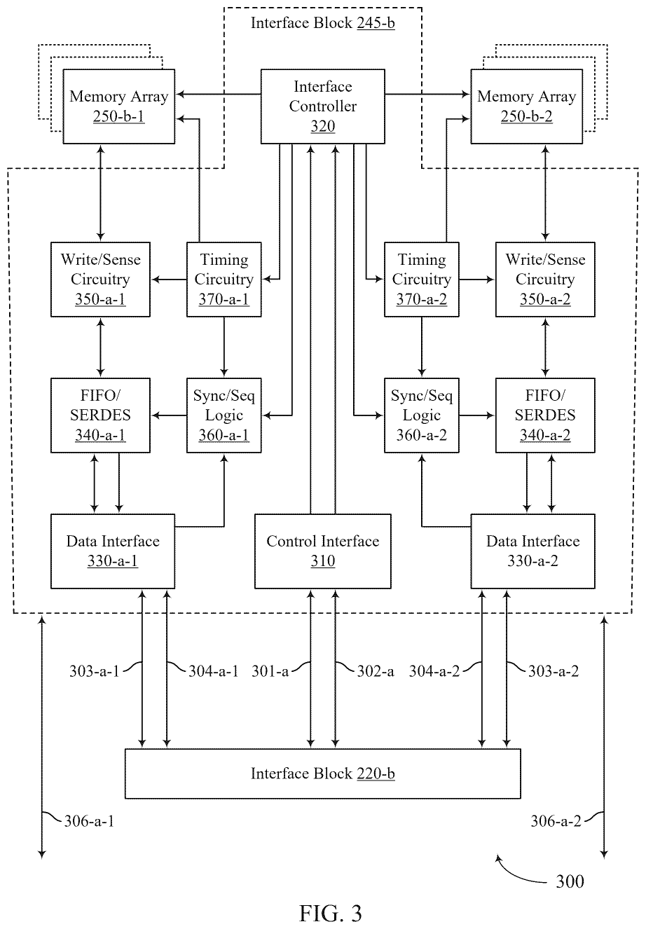

FIG. 3 shows an example of an interface architecture 300 that supports techniques for in-situ testing of stacked semiconductor components in accordance with examples as disclosed herein. The interface architecture 300 illustrates an example of an interface block 245-b (e.g., of a die 240) coupled with an interface block 220-b (e.g., of a die 205). The interface block 245-b may be communicatively coupled with the interface block 220-b via one or more of a bus 301, a bus 302, a bus 303, and a bus 304, each of which may be examples of one or more signal paths of a bus 221 and a bus 246, as well as a bus 255, where applicable. The interface block 245-b may further be coupled with one or more buses 306 (e.g., power delivery buses, PDN TRVs, communicative buses), which may deliver power directly to components of the interface block 245-b or memory arrays 250-b (e.g., or some other component of a die 240).

The interface block 245-b includes a control interface 310 (e.g., a command interface), which may be configured to communicate signaling with the interface block 220-b. For example, the control interface 310 may include circuitry (e.g., a receiver, one or more latches) configured to receive control signaling (e.g., modulated control signaling, access command signaling, configuration signaling, address signaling, such as row address signaling or column address signaling) via the bus 301-a. The control interface 310 also may include circuitry configured to receive clock signaling (e.g., clock signaling associated with the control interface 310, clock signaling having one or more phases, such as true and complement phases, dk_t/c signaling from the interface block 220-b) via the bus 302-a, which the control interface 310 may use for receiving the control signaling of the bus 301-a (e.g., for triggering the one or more latches). The control interface 310 may transmit (e.g., forward) the control signaling and the clock signaling (e.g., for timing of other operations of the interface block 245-b) to an interface controller 320.

The interface block 245-b also includes two data interfaces 330 (e.g., data interfaces 330-a-1 and 330-a-2), which also may be configured to communicate signaling with the interface block 220-b. Each data interface 330 may include corresponding buses and circuitry, the operation of which may be associated with (e.g., controlled by, coordinated with, operated based on) control signaling via the control interface 310. Although the example of interface block 245-b includes two data interfaces 330 associated with the control interface 310 (e.g., in a “channel pair” arrangement, in a “pseudo-channel pair” arrangement), the described techniques for an interface block 245 may include any quantity of one or more data interfaces 330, and associated buses and circuitry, for a given control interface 310 of the interface block 245.

Each data interface 330 may be associated with respective data path circuitry, which may include respective first-in-first-out (FIFO) and serialization/deserialization (SERDES) circuitry (e.g., FIFO/SERDES 340), respective write/sense circuitry 350, respective synchronization and sequencing circuitry (e.g., sync/seq logic 360), and respective timing circuitry 370, along with interconnecting signal paths (e.g., one or more buses). However, in some other examples, data path circuitry may be arranged in a different manner, or may include different circuitry components, which may include circuitry that is dedicated to respective data paths, or shared among data paths, or various combinations thereof. Each data interface 330 also may be associated with a respective set of one or more memory arrays 250. In some examples, each memory array 250 may be understood to include respective addressing circuitry such as bank logic or decoders (e.g., a row decoder, a column decoder), or memory cell sense amplifier circuitry, among other array circuitry. However, in some other examples, at least a portion of such circuitry may be included in an interface block 245.

Each data interface 330 may include circuitry (e.g., one or more latches, one or more drivers) configured to communicate (e.g., receive, transmit) data signaling (e.g., modulated data signaling, DQ signaling) via a respective bus 303. Each data interface 330 also may include circuitry to communicate clock signaling via a respective bus 304, which may support clock signal reception by the data interface 330 (e.g., first clock signaling associated with the data interface 330, clock signaling having one or more phases, such as true and complement phases, DQS_t/c signaling from the interface block 220-b, clock signaling associated with data reception or write operations), or clock signal transmission by the data interface 330 (e.g., second clock signaling associated with the data interface 330, RDQS_t/c signaling to the interface block 220-b, clock signaling associated with data transmission or read operations), or both. In some examples, a data interface 330, a bus 303, or a combination of a bus 303 and a bus 304, may be associated with a “pseudo-channel,” and multiple pseudo-channels may be associated with the same control interface 310 or the same control bus (e.g., a bus 301, a combination of a bus 301 and a bus 302). In some implementations, pseudo-channels of multiple interface blocks 245 may be grouped together (e.g., functionally, logically, electrically, such as through hard-wired signal paths or multiplexing circuitry) to support a channel set (e.g., associated with a corresponding host interface 216). Each data interface 330 may transmit clock signaling (e.g., received clock signaling, DQS_t/c signaling) to sync/seq logic 360 via a respective bus (e.g., for timing of other operations of the interface block 245-b).

The interface controller 320 may support various functionality (e.g., control functionality, configuration functionality) of the interface block 245-b for accessing or otherwise managing operations of the coupled memory arrays 250. For example, the interface controller 320 may support access command coordination or configuration, latency or timing compensation, access command buffering (e.g., in accordance with a FIFO or other organizational scheme), mode registers or logic for configuration settings, or test functionality (e.g., evaluation functionality, BIST functionality), among other functions or combinations thereof. For each data path of the interface block 245 (e.g., associated with a respective data interface 330), the interface controller 320 may be configured to transmit signaling (e.g., address signaling, such as row address or row activation signaling) to the respective memory arrays 250 via a bus. For each data path of the interface block 245, the interface controller 320 may communicate signaling (e.g., timing signaling, which may be based on clock signaling received from the control interface 310, configuration signaling) with respective timing circuitry 370 and sync/seq logic 360 via respective buses.

For each data path, the respective timing circuitry 370 may support timing of various operations (e.g., activations, coupling operations, signal latching, signal driving) relative to timing signaling received from the interface controller 320. For example, timing circuitry 370 may include a timing chain (e.g., a global column timing chain) configured to generate one or more clock signals or other initiation signals for controlling operations of the respective data path, and such signaling may include transitions (e.g., rising edge transitions, falling edge transitions, on/off transitions) that are offset from, at a different rate from, or otherwise different from transitions of signaling from the interface controller 320 to support a given operation or combination of operations. For example, timing circuitry 370 may be configured to transmit signaling (e.g., address signaling, such as column address or column activation signaling) to the respective memory arrays 250, to transmit signaling to the respective write/sense circuitry 350 (e.g., latch or driver timing signaling), and to transmit signaling to the respective sync/seq logic (e.g., timing signaling).

For each data path, the respective FIFO/SERDES 340 may be configured to convert between data signaling of a first bus width (e.g., a relatively wide bus width, a data read/write (DRW) bus, a bus for communications with write/sense circuitry 350 having a relatively larger quantity of signal paths) and a second bus width (e.g., a relatively narrow bus width, a bus for communications with a data interface 330 having a relatively smaller quantity of signal paths). In some examples, such a conversion may be accompanied by changing a rate of signaling between signaling from the data interface 330 and the write/sense circuitry 350 (e.g., to maintain a given throughput). In various examples, the FIFO/SERDES 340 may receive data signaling from the data interface 330 and transmit data signaling to the write/sense circuitry 350 (e.g., to support a write operation), or may receive data signaling from the sense circuitry 350 and transmit data signaling to the data interface 330 (e.g., to support a read operation). In some examples (e.g., to support a read operation), the FIFO/SERDES 340 may be configured to transmit clock signaling (e.g., RDQS_t/c signaling) to the data interface 330, which may be forwarded to the interface block 220-b.

The timing or other synchronization of operations performed by the FIFO/SERDES 340 may be supported by one or more clock signals, among other signaling, received from the respective sync/seq logic 360. For example, the sync/seq logic 360 may generate or otherwise coordinate clock signaling to support the different rates of signaling of different buses (e.g., based on received clock signaling). Additionally, or alternatively, the FIFO/SERDES 340 may operate in a direction (e.g., for data transmission to a data interface 330, for data reception from a data interface 330) or other mode based on configuration signaling received from the sync/seq logic 360.

For each data path, the respective write/sense circuitry 350 may be configured to support the accessing (e.g., data signaling, write signaling, read signaling) of the respective set of one or more memory arrays 250. For example, the write/sense circuitry 350 may be coupled with the memory arrays 250 via a bus (e.g., a global input/output (GIO) bus), which may include respective signal paths associated with each memory array 250, or may include signal paths that are shared for all of the memory arrays 250 of the set, in which case the memory array circuitry may include multiplexing circuitry operable to couple the bus with a selected one of the memory arrays 250. In some examples, a bus between the write/sense circuitry 350 and the set of one or more memory arrays 250 may include a same quantity of signal paths as a bus between the write/sense circuitry 350 and the FIFO/SERDES 340 (e.g., for signaling GIO[287:0]) or a same quantity of signal paths as a quantity of columns in each memory array 250. In some other examples, the memory arrays 250 may include a quantity of columns that is an integer multiple of the quantity of signal paths of the bus, in which case the memory array circuitry (e.g., each memory array 250) may include decoding circuitry operable to couple a subset of columns of memory cells, or associated circuitry, with the bus.

To support write operations, the write/sense circuitry 350 may be configured to drive signaling that is operable to write one or more logic states to memory cells of the memory arrays 250 (e.g., based on received data, based on received timing signaling, based on data signaling received via a bus 303 and on control signaling received via a bus 301-a). In some examples, such signaling may be transmitted to supporting circuitry of or otherwise associated with the memory arrays 250 (e.g., as an output of signals corresponding to logic states to be written), such as sense amplifier circuitry, voltage sources, current sources, or other driver circuitry operable to apply a bias across a storage element of the memory cells (e.g., across a capacitor, across a ferroelectric capacitor), or apply a charge, a current, or other signaling to a storage element of the memory cells (e.g., to apply a current to a chalcogenide or other configurable memory material, to apply a charge to a gate of a NAND memory cell), among other examples.

To support read operations, the write/sense circuitry 350 may be configured to receive signaling that the write/sense circuitry 350 may further amplify for communication through the interface block 245-b. For example, the write/sense circuitry 350 may be configured to receive signaling corresponding to logic states read from the memory arrays 250, but at a relatively low driver strength (e.g., relatively ‘analog’ signaling, which may be associated with a relatively low drive strength of sense amplifiers of the memory arrays 250). The write/sense circuitry 350 may thus include further sense amplification (e.g., a data sense amplifier (DSA) between signal paths between the write/sense circuitry and the set of one or more memory arrays and respective signal paths between the write/sense circuitry and the FIFO/SERDES), which each may have a relatively high drive strength (e.g., for driving relatively ‘digital’ signaling).

The features of the interface architecture 300 may be duplicated in various quantities and arrangements to support a semiconductor system having multiple dies, such as various examples of a system 200. In an example implementation, each die 240 may be configured with 64 instances of the interface block 245-b, which may support a data signaling width of 9,216 signal paths for each die 240 (e.g., where each bus 303 of a channel pair is associated with 72 signal paths). For a system 200 having a stack of eight dies 240 coupled with a die 205, the die 205 may thus be configured with 512 instances of the interface block 220-b, thereby supporting an overall data signaling width of 73,738 signal paths for the system 200. However, in other implementations, dies 205 and dies 240 may be configured with different quantities of interface blocks 220 and 245, respectively, and a system 200 may be configured with different quantities of dies 240 per die 205.

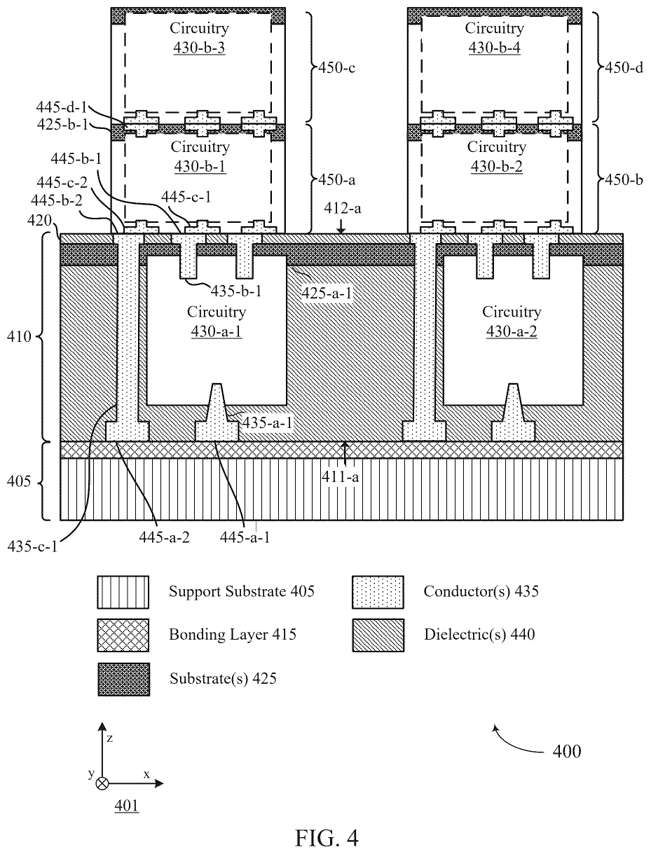

FIG. 4 shows an example of a semiconductor system 400 that supports techniques for testing of stacked semiconductor components in accordance with examples as disclosed herein. The semiconductor system 400 may be an example of a semiconductor system formed after a sequence of operations, which may support manufacturing a system 100 or a portion thereof, a system 200 (e.g., a unit that supports the functionality of a die 205 and one or more dies 240), or other stacked semiconductor systems. Aspects of the semiconductor system 400 may be described in accordance with an x-direction, a y-direction, and a z-direction of a coordinate system 401.

The semiconductor system 400 may include a support substrate 405 (e.g., a support structure, a WSS) bonded with a first component 410 (e.g., a first semiconductor component, a semiconductor wafer). In some cases, a bonding layer 415 (e.g., bonding material) may be used to bond the first component 410 to the support substrate 405. The support substrate 405 may be an example of a supportive substrate (e.g., a support base, a support component, a supportive silicon plate, a glass plate) used during manufacturing processes. For example, the support substrate 405 may provide a surface for bonding (e.g., mounting) one or more other layers or components, and may provide structural support for at least the first component 410. After at least some of the manufacturing operations are completed, the first component 410 may be debonded from the support substrate 405. In some examples, the support substrate 405 may be reused after completion and debonding of one manufacturing process for a subsequent manufacturing process (e.g., may be a “cradle” or “bed” used in photolithography). In some examples, the support substrate 405 may be an example of a wafer support system (WSS) that supports manufacturing the first component 410 (e.g., before stacking with other components). Additionally, or alternatively, the support substrate 405 may be discarded after a manufacturing operation.

The first component 410 may include a layer 420 (e.g., including conductive material for one or more contacts or an RDL, including non-conductive material in between one or more contacts), and one or more substrates 425. The first component 410 may also include circuitry 430 (e.g., transistor circuitry, signal paths, electrical components), conductors 435 (e.g., vias, contacts, one or more electrically conductive materials), and one or more dielectrics 440 (e.g., one or more electrically non-conductive materials). In various examples, the first component 410 (e.g., circuitry 430) may include front end of line (FEOL) circuitry (e.g., transistor circuitry), back end of line (BEOL) circuitry (e.g., interconnection circuitry, one or more conductive paths formed above transistor circuitry), or both. In some examples, a substrate 425 may be doped to form at least a portion of the circuitry 430 (e.g., to form transistors of circuitry 430). For example, at least a portion of circuitry 430-a may be formed from a doped portion of the substrate 425-a-1.

In some examples, aspects of semiconductor components (e.g., dies, wafers) may be described with reference to a front side and a back side, which may be opposite sides of a semiconductor component relative to a substrate 425. For example, a front side of the component 410 may be a side (e.g., a side along the z-direction, a side in an xy-plane) of the component 410 that is on the same side of the substrate 425-a-1 of the component 410 that is doped to form at least a portion of the circuitry 430 (e.g., a side upon which FEOL and BEOL circuitry is formed over the substrate). A back side of the component 410 may be opposite the front side (e.g., along the z-direction), which may be on a side of the substrate 425-a-1 that, in some examples, is not doped).

Each instance of circuitry 430 may be coupled with one or more conductors. For example, the circuitry 430-a-1 may be coupled with a conductor 435-a-1 and a conductor 435-b-1, among others. One or more conductors 435 may include or be coupled with a respective contact at a surface of the first component 410. For example, the first component 410 may include one or more operative contacts 445-a (e.g., operative pads) at a surface 411-a (e.g., a first surface, a front-side surface) of the first component 410. Additionally, or alternatively, the first component 410 may include one or more contacts 445-b at a surface 412-a (e.g., a second surface, a back-side surface) of the first component 410. The first component 410 also may include one or more additional conductors not coupled with circuitry 430. For example, the first component 410 may include one or more conductors 435-c, such as a conductor 435-c-1 (e.g., a TSV, TRV), which may extend through the thickness of the first component 410 (e.g., along the z-direction). The conductor 435-b-1 may also include or be coupled with an operative contact 445-a-2 at the surface 411-a and a contact 445-b-2 at the surface 412-a. In some examples, the contacts 445-a may be operable in use for accessing the circuitry 430-a-1 or for accessing one or more components bonded with the contacts 445-b. Additionally, or alternatively, the contacts 445-b may be used for bonding the first component 410 with other components.

In some examples, the first component 410 may be an example of a wafer upon which additional components (e.g., semiconductor dies) may be stacked. For example, the system 400 may include second components 450-a, 450-b, 450-c, and 450-d, which may be bonded in stacks with the first component 410. The second components 450 may each include a respective substrate 425-b, circuitry 430-b, and one or more contacts 445-c and 445-d coupled with circuitry 430-b. In some examples, at least a portion of circuitry 430-b (e.g., one or more transistors of the circuitry 430-b-1, complementary metal-oxide semiconductor (CMOS) circuitry) may be formed from a doped portion of a substrate 425-b. In some cases, second components 450 may be bonded to a back side of the first component 410, which may include coupling circuitry 430-b with circuitry 430-a of the first component 410. For example, the second component 450-a may include a contact 445-c-1 that may be bonded with the contact 445-b-1. Circuitry 430-b of the second components 450 may additionally couple with conductors 435-b. For example, a contact 445-c-2 may be bonded with the contact 445-b-2. In some other examples, components 450 may be bonded to a front side of a component 410. In some cases, the circuitry 430-a may function as interface circuitry for accessing circuitry 430 of the second components 450. In such an example, the first component 410 may be referred to as an interface wafer. The one or more second components 450 may be operable to exchange signaling via a device coupled with the operative contacts 445-a, which may include signaling through circuitry 430 or bypassing circuitry 430.

A second component 450 of a stack may, in some cases, be associated with defects (e.g., a defect of the second component 450, a defect of bonding between the second component 450 and another component), which may result in an entire stack that includes the second component 450 being compromised. Such a defect may cause an entire stack to be discarded. For example, the second component 450-b may be a KGD, but may experience a bonding defect between the second component 450-b and the first component 410, or between the second component 450-b and the second component 450-d, or may be associated with a defect within the second component 450-b itself. Thus, although bonding between the second component 450-d and one or more additional stacked dies may have no defects (“good” dies are continually stacked after the “failed” die), and the second component 450-d and one or more additional dies may be KGDs, an entire stack of dies including the second component 450-b, 450-d, and any additional dies may be discarded after manufacture regardless due to the defect(s). For example, the defects associated with the second component 450-b may prevent access to subsequent stacked dies (e.g., one die “failing” causes other dies to fail) including the second component 450-d.

In some examples, the first component 410 may be debonded from the support substrate 405 to enable testing of the stacks of second components 450 using one or more contacts 445-a at the surface 411-a (e.g., operative/operational pads). For example, after debonding the first component 410 from the support substrate 405, a probe may be used to contact operative contacts 445-a at the front side of the first component 410 to determine if the first component 410 or one or more of the second components 450 are associated with one or more defects. However, such debonding may not be performed until after at least the components 450 are stacked, and the support substrate 405 may prevent access to the operative contacts 445-a during die stacking. Therefore, components may be discarded after a stack is complete, which may waste KGDs. In accordance with examples as disclosed herein, a first semiconductor component may thus be formed with circuitry that enables in-situ (e.g., in place during manufacture) evaluation of dies, including evaluations of dies during various stages of die stacking on the first semiconductor component.

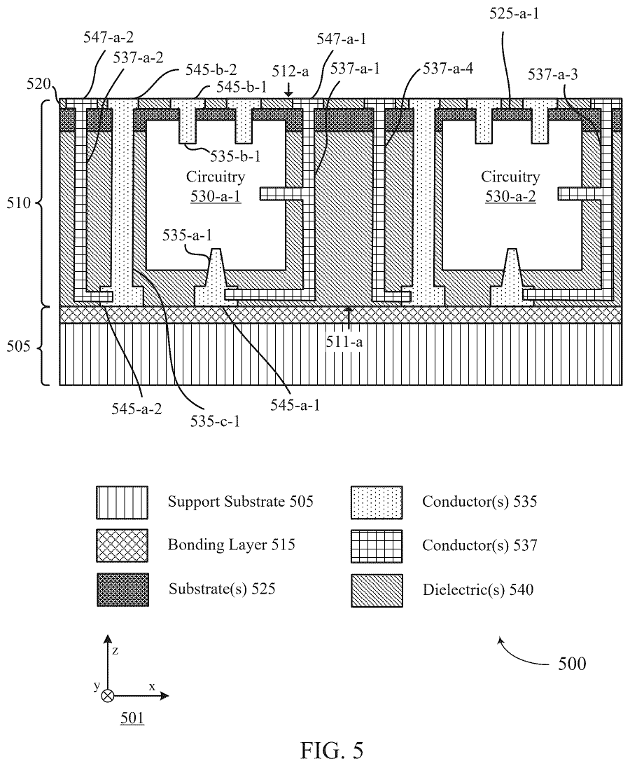

FIGS. 5-8 show examples of operations for forming a semiconductor system 500 (e.g., a heterogeneous device, a semiconductor system of heterogeneous dies, a heterogeneous HBM system, a heterogeneous TCDRAM system) that support techniques for in-situ testing of stacked semiconductor components in accordance with examples as disclosed herein. For example, FIGS. 5 through 8 may illustrate aspects of a sequence of operations that may support manufacturing a system 100 or a portion thereof, a system 200 (e.g., a unit that supports the functionality of a die 205), or other stacked semiconductor system, which may reduce die loss during manufacturing. Aspects of the semiconductor system 500 may be described with reference to an x-direction, a y-direction, and a z-direction of a coordinate system 501. Operations illustrated in and described with reference to FIGS. 5 through 8 may be performed by a manufacturing system, such as a semiconductor fabrication system configured to perform additive operations (e.g., deposition, epitaxy, bonding), subtractive operations (e.g., etching, trenching, planarizing, polishing), modifying operations (e.g., oxidizing, doping, reacting, converting), and supporting operations (e.g., masking, patterning, photolithography, aligning), among other operations that support the described techniques.

In some examples, such a stacked architecture may be implemented as part of an HBM system or a TCDRAM system, and may support solutions for memory-centric logic, such as graphics processing units (GPUs), among other implementations. For example, such coupling may include one or more processors being implemented in a same semiconductor die as at least a portion of an HBM system or a TCDRAM system (e.g., as part of a logic die), or one or more processors being implemented in a die that is directly coupled (e.g., fused) with another die that includes at least a portion of an HBM system or a TCDRAM system, or otherwise coupled with another die that includes at least a portion of an HBM system or a TCDRAM system (e.g., via a silicon interposer or other intervening component). Unlike cache-based memory, a TCDRAM system may not be backed by a level of external memory with the same physical addresses. For example, a TCDRAM system may be associated with and located within a dedicated base address, where each portion of the TCDRAM system may be non-overlapping within the address. In some examples, a host processor of an HBM system may be external to memory dies, whereas in TCDRAM, a host processor may be internal to a memory die.

FIG. 5 illustrates a portion of the semiconductor system 500 after a first set of one or more manufacturing operations. For example, the semiconductor system 500 may include a support substrate 505 (e.g., a WSS, such as a silicon plate or glass plate) and a first component 510, which may be examples of a support substrate 405 and a first component 410. The first component 510 (e.g., a wafer of one or more dies 205, or another lower wafer in a stack) may include a layer 520 (e.g., including conductive material for one or more contacts or an RDL, including non-conductive material in between one or more contacts) and a substrate 525-a-1 (e.g., a semiconductor substrate, a crystalline semiconductor substrate, multiple substrates of a reconstructed wafer). The first component 510 may also include circuitry 530 (e.g., transistor circuitry, signal paths, electrical components), conductors 535 and conductors 537 (e.g., vias, contacts, one or more electrically conductive materials), and one or more dielectrics 540 (e.g., one or more electrically non-conductive materials).

In various examples, the first component 510 (e.g., circuitry 530) may include front end of line (FEOL) circuitry (e.g., transistor circuitry), back end of line (BEOL) circuitry (e.g., interconnection circuitry, one or more conductive paths formed above transistor circuitry), or both. For example, circuitry 530 may include interface blocks 220, logic blocks 225, logic blocks 230, controllers 215, host processors 210, sensor circuitry (e.g., sensors 237, sensors 275), storage circuitry (e.g., memory arrays 250, non-volatile storage 235, non-volatile storage 270), other circuitry (e.g., graphics circuitry, peripheral circuitry), or any combination thereof. In some examples, a substrate 525 may be doped to form at least a portion of the circuitry 530 (e.g., to form transistors of circuitry 430). For example, at least a portion of circuitry 530-a (e.g., one or more transistors of the circuitry 530-a, complementary metal-oxide semiconductor (CMOS) circuitry) may be formed from a doped portion of the substrate 425-a-1 (e.g., a doped semiconductor material, a doped crystalline semiconductor).

In some examples, the first component 510 may be formed from a semiconductor wafer. In some other examples, the first component 510 may be formed with multiple semiconductor die portions (e.g., relatively smaller dies, dies each including a respective subset of components of a logic unit) that are bonded with a carrier and interconnected with each other. At least some, if not all of the die portions may individually satisfy an evaluation. For example, the die portions may be known good dies (KGDs) before interconnection, where a KGD may be dies that have been evaluated for proper operation before stacking. The die portions may examples of chiplets (e.g., logic chiplets), and each chiplet may include a respective portion of circuitry that may be otherwise associated with functionality of a relatively larger die (e.g., a die portion including a portion of circuitry of an original die as with a single wafer example, where the original die may be an interface die cut from a wafer).

In some such examples, the circuitry 530-a may be examples of different portions of circuitry of one or more larger dies that may be represented by the first component 510. For example, in such a case, the circuitry 530-a-1 may be coupled with the circuitry 530-a-2 (e.g., using an RDL in the layer 520 or elsewhere to function as a larger die). Additionally, or alternatively, the circuitry 530-a-1 and 530-a-2 may each represent portions of a reconstructed wafer including multiple chiplets. In such examples, the substrate 525-a-1 may include two separate substrates (e.g., with a dielectric in between them along the x-direction or y-direction), such that each of the circuitry 530-a-1 and 530-a-2 may include a portion of the substrate 525-a-1 as their own respective substrate of a chiplet, or of multiple chiplets.

In some examples, circuitry 530-a-1 may be different than circuitry 530-a-2 (e.g., of different chiplets in a heterogeneous chiplet configuration) or may include the same circuitry. For example, the circuitry 530-a-1 may include memory interface circuitry and the circuitry 530-a-2 may include host processor circuitry, among other examples of differentiation among dies. In some examples, circuitry 530-a-1 may include circuitry associated with one or more units 280-a-1 and may not include at least some of the circuitry associated with one or more units 280-a-2 (e.g., a host system 105 or a host processor 210 may be separately coupled, such as in an HBM implementation). In some other examples, circuitry 530-a-1 may not include circuitry associated with the one or more units 280-a-1 (e.g., the one or more units 280-a-1 may be separately coupled) and may include circuitry associated with one or more units 280-a-2 (e.g., such as host processors 210 and controllers 215). In some examples, each of the circuitry 530-a-1 and the circuitry 530-a-2 (e.g., where each represent circuitry of a different chiplet) may include a bonding layer (e.g., bonding material), which may be opposite a substrate 525 of respective chiplets or dies (e.g., along the z-direction), and may include one or more alignment features included in the bonding layer (e.g., used in bonding processes for bonding chiplets in the component).

The circuitry 530-a may be coupled with conductors 535-a having operative contacts 545-a at a surface 511-a (e.g., a front-side surface) of the first component 510 (e.g., conductor 545-a-1 coupled with operative contact 545-a-1). The circuitry 530-a may also be coupled with one or more conductors 535-b coupled with respective contacts 545-b at a surface 512-a (e.g., a back-side surface) of the first component 510 (e.g., conductor 535-b-1 coupled with contact 545-a-2). The first component 510 may additionally include one or more conductors 535-c coupled with respective contacts 545-a, as well as one or more dielectrics 540.

The first component 510 may also include one or more conductors 537 that enable testing of stacked dies during manufacturing. For example, the first component 510 may include a conductor 537-a-1, a conductor 537-a-2, a conductor 537-a-3, a conductor 537-a-4, or any combination thereof. In some cases, a conductor 537 may be coupled with a respective first interface at the surface 511-a. For example, the conductor 537-a-1 may be coupled with the operative contact 545-a-1 and the conductor 537-a-2 may be coupled with the operative contact 545-a-2. In some examples, the conductors 537-a-1 through 537-a-4 may include one or more vias (e.g., TSVs through the substrate 525-a-1), electrodes or other conductive elements that may couple with operative contacts 545. In some cases, the first component 510 may include a respective conductor 537 for each operative contact 545-a of the first component 510 (e.g., in a 1-to-1 relation as illustrated in FIG. 5).

The conductors 537-a may also include a second respective interface at the surface 512-a. For example, each of the conductors 537 may include a respective test pad 547 at least partially, if not fully, on the surface 512-a, where at least one of the one or more conductors 537 may include a respective conductor portion through the semiconductor substrate 525-a-1. For example, the conductor 537-a-1 may include a TSV through the substrate 525-a-1 to couple with a test pad 547-a-1. In some cases, test pads 547 may be a same or different material as corresponding conductors 537, or conductors 535, or both.

In some examples, conductors 537 may be coupled with circuitry of the first component 510. For example, the conductor 537-a-1 may include one or more vias, electrodes, or both, coupling with the circuitry 530-a-1. Additionally, or alternatively, one or more of the conductors 537 may omit a test pad 547 (e.g., may end directly at the surface 512-a). A test pad 547 may, in some cases, couple directly with a corresponding operative contact 545 (e.g., where an operative contact 545-a may, in some cases, be referred to as a secondary test pad). For example, the test pad 547-a-1 may couple directly to the operative contact 545-a-1 via the conductor 537-a-1. Additionally, or alternatively, a test pad 547 may couple indirectly with a corresponding operative contact 545-a via circuitry of the first component 510 (e.g., the circuitry 530-a-1 may be an example of or include a portion of test functioning circuits for testing one or more components).

In some examples, the first component 510 may include an RDL on the back side of the first component 510 (e.g., above the substrate 525 along the z-direction) which may be coupled with the test pads 547, contacts 545-b, or both. For example, an RDL may be included in the layer 520, and may include one or more levels of conductive interconnects (e.g., conductive traces) along the x-direction, y-direction, or both. In some examples, such an RDL may electrically connect one part of a semiconductor package of the first component 510 to another (e.g., coupling contacts 545 and test pads 547 with conductors 535 and 537). In some examples, the circuitry 530-a may include a doped portion of the substrate 525-a-1 (e.g., a front-side portion), and at least one conductor 537 may include a conductor portion (e.g., TSV) formed between the surface 512-a and the side of the semiconductor substrate including the doped portion. In some examples, the test pads 547 may be placed outside an area for bonding additional semiconductor components. Various portions of the first component 510, including the conductors 537-a and corresponding test pads 547-a, may be formed using one or more additive operations, subtractive operations, modifying operations, supporting operations, or any combination thereof.

In some cases, the first set of manufacturing operations may include bonding the first component 510 to the support substrate 505. For example, the surface 511-a at the front side of the first component 510 may be bonded to the support substrate 505 (e.g., using a bonding layer 515, a fusion bonding operation, a thermal compression operation, a mass reflow operation, a hybrid bonding operation, or a combination thereof). In some examples, the first set of manufacturing operations may also include forming the RDL (e.g., in the layer 520).

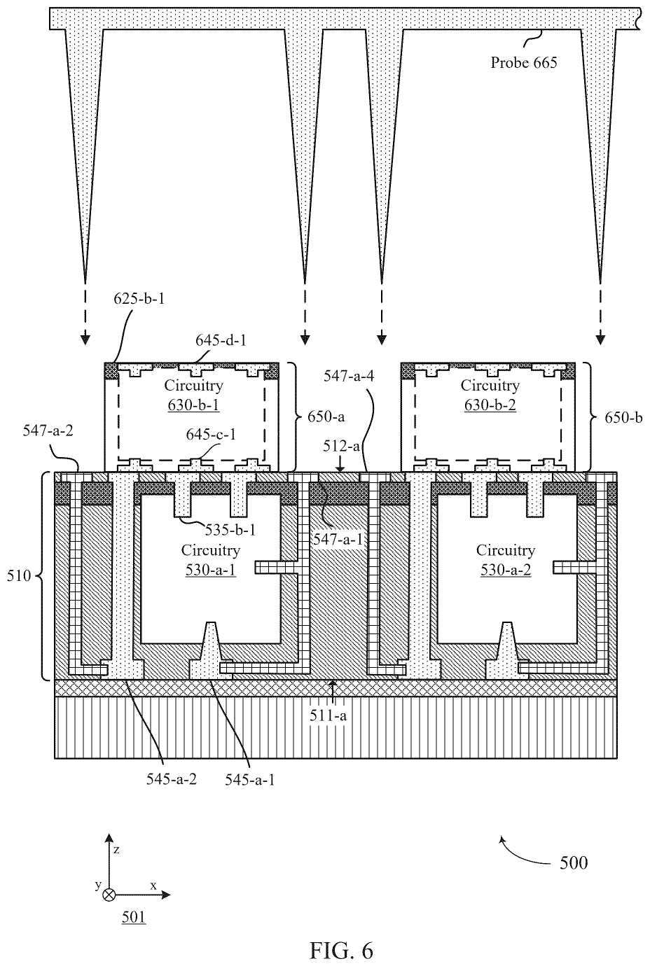

FIG. 6 illustrates a portion of the semiconductor system 500 after a second set of one or more manufacturing operations. For example, the second set of manufacturing operations may include bonding one or more components 650 (e.g., semiconductor components, semiconductor dies) to the surface 512-a. Each component 650 may include a respective substrate 625-b, respective circuitry 630-b, and respective contacts 645-c. In some cases, a component 650 and a first component 510 may be bonded in a front-to-back bonding arrangement (e.g., chip-to-wafer or chip to chiplet(s) front-to-back bonding). Additionally, or alternatively, a component 650 may be bonded to a first component in another arrangement (e.g., back-to-back, front-to-front, back-to-front).

The bonding of the components 650 to the first component 510 may couple (e.g., electrically) respective contacts 645-a with corresponding contacts 545-b of the first component 510. For example, the contact 645-c-1 of the component 650-a may be bonded (e.g., fusion bonded) with the contact 545-b-1 and may thus be coupled with the circuitry 530-a-1. In some cases, the test pads 547 may be located on the die edge area or scribe lane outside of an area where the components 650 are bonded. In some examples, the circuitry 630 of the components 650 may be operable based on the circuitry 530-a. In some cases, operation or access may be supported by using the operative contacts 545-a in connection with the circuitry 530-a-1, or using operative contacts 545-a in direct connection (e.g., the operative contact 545-a-2). In some examples, the components 650 may each include one or more contacts 645-d at an opposite side of their respective substrates 625-b as the side of the contacts 645-c. For example, the component 650-a may include a contact 645-d-1, among other contacts 645-d. In some cases, the contacts 645-d may couple with respective circuitry 630-b (e.g., the circuitry 630-b-1 or the circuitry 630-b-2) and additional components 650 (e.g., stacked on top of the second components 650-a and 650-b). The system 500 may include any quantity of stacks of dies (e.g., any quantity of stacks of components 650).

In some examples, the second set of manufacturing operations may include evaluating an operation (e.g., functionality) of at least one instance of the circuitry 630-b of the components 650. For example, a probe 665 (e.g., an evaluation probe) may be used for evaluations by coupling with conductors 537, and in some cases may be lowered until in contact with one or more of the test pads 547 or portions of the conductors 537 extending to surface 512-a. In some examples, the probe 665 may be electrically coupled with a test pad 547-a-1 of a conductor 537-a-1, which may couple directly to the circuitry 530-a-1, or indirectly through the operative contact 545-a-1. Thus, the probe 665 may communicate (e.g., transmit, receive, exchange) signaling with the circuitry 630-b (e.g., for testing). In some examples, coupling the probe 665 with the one or more conductors 537 or test pads 547 may alter the conductors or test pads. For example, probing of the test pads 547 may cause irregularities (e.g., damage, discontinuities, dislocations, imprints, deformation) of the test pads 547, or a change in material composition of the test pads 547, which may be indicative of the probing or evaluation operations.

In some examples, evaluation may be used to detect one or more defects by exchanging the signaling. For example, an evaluation may detect whether one or more defects are present in the bonding of components 650-a and 650-b to the surface 512-a (e.g., defects related to a failed fusion between contacts 545-b and contacts 645-c). In an example, such testing may test performance of dies (e.g., the components 650) and their circuitry (e.g., the circuitry 630-b) while coupled with support circuitry (e.g., the first component 510, such as a wafer or one or more chiplets including support circuitry 530-a for the components 650). For example, the components 650-a and 650-b may be examples of KGDs tested previously to ensure valid operation of the components themselves (e.g., of the circuitry 630-b-1 and 630-b-2), and the testing via the probe 665 may evaluate their functionality after bonding. Additionally, or alternatively, the evaluation operation may be used to detect whether the components 650-a and 650-b have one or more internal defects (e.g., to perform testing of dies themselves during a sequence of stacking operations).

Although the example of FIG. 6 illustrates an orientation of test pads 547 associated with a back side of the first component 510 among other relative orientations, such components and devices may be oriented in any other orientation or configuration. For example, one or more dies may be stacked in a front side arrangement on a front side of the substrate 525-a-1 of the first component 510, with test pads on the surface 511-a at the fronts side of the substrate. Additionally, or alternatively, the second components 650 may be bonded with the first component in a front to front arrangement, a back to front arrangement, a back to back arrangement, etc. In some cases, the operative contacts 545 may also be at the back side on the surface 512-a.

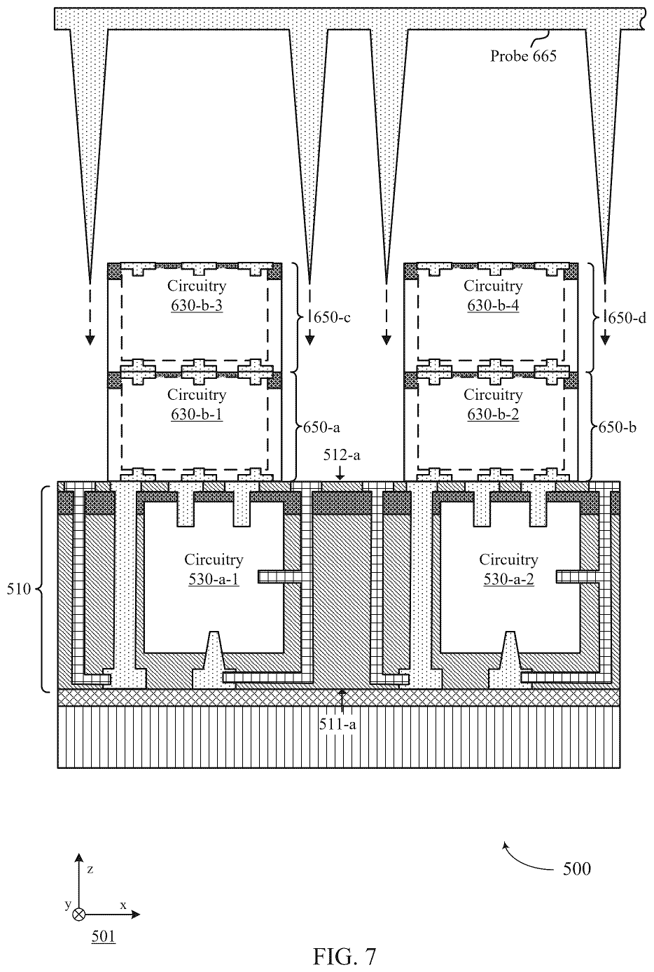

FIG. 7 illustrates a portion of the semiconductor system 500 after a third set of one or more manufacturing operations. For example, the third set of manufacturing operations may include bonding one or more additional components 650 (e.g., semiconductor dies) to the components 650-a and 650-b based on the evaluation operation performed in the second set of operations indicating a successful operation. For example, a second component 650-c may be bonded with the second component 650-a based on the evaluation operation indicating a lack of defects (or quantity of defects under a threshold value) identified when testing the second component 650-a (e.g., due to bonding or in the circuitry itself), and a second component 650-d may be bonded with the second component 650-b after testing the second component 650-b. The components 650-c and 650-d may include circuitry 630-b-3 and 630-b-4, respectively, which may be operable based on a coupling with circuitry 630-b of the components 650-a and 650-b, respectively, or directly with the circuitry 530-a or operative contacts 545-a (e.g., using TRVs). The components 650-a and 650-c may represent a first stack of semiconductor dies, and the components 650-b and 650-d may represent a second stack of semiconductor dies. In some examples, stacking the components 650 may involve the use of one or more bonding processes (e.g., front to back), including compression bonding, mass reflow bonding, or hybrid bonding.

The third set of manufacturing operations may also include evaluating an operation of the one or more newly-bonded components 650-c and 650-d and/or their respective circuitry 630-b-3 and 630-b-4. In some cases, the probe 665 may exchange signals with the circuitry 630-b-3 and the circuitry 630-b-4 via interconnect regions or other circuitry, which may connect one or more of the second components 650-a through 650-d with the circuitry 530-a-1 or directly with operational contacts 545-a of the first component 510.

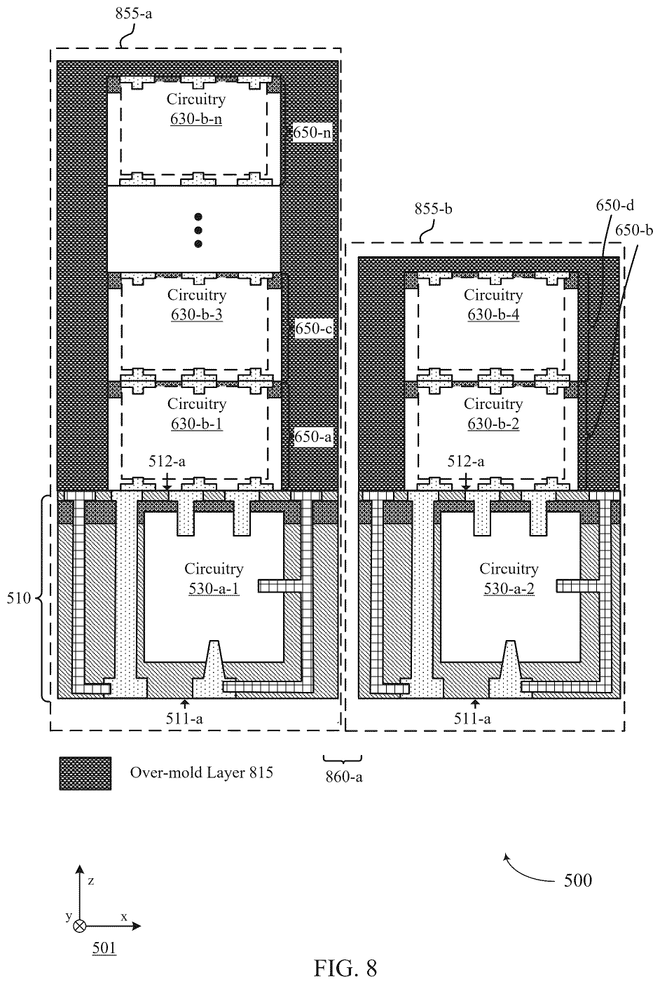

FIG. 8 illustrates a portion of the semiconductor system 500 after a fourth set of one or more manufacturing operations. For example, the fourth set of manufacturing operations may include bonding one or more additional components to one stack of components 650, and refraining from bonding additional components 650 to another stack of components 650, based on the evaluation operation performed in the third set of operations.

For example, the evaluation operation in FIG. 7 may indicate that the evaluation of operation of the circuit 630-b-3 was successful (e.g., that no defects were identified). Based on the successful evaluation, one or more additional second components 650 may be bonded (e.g., stacked) in the first stack. For example, one or more second components 650 up to and including a second component 650-n including circuitry 630-b-n may be bonded to the first stack based on a successful evaluation of one or more component after a subsequent bonding to a previously-bonded second component. In some examples, up to N components (e.g., up to N semiconductor dies) may be bonded, or stacked, in the first stack. In some cases, the system 500 may represent an 8-Hi HBM or 8-Hi TCDRAM system, where 8-Hi may indicate that N=8, and up to 8 dies may be stacked in a single stack, including the first stack with the components 650-a, 650-b, up to 650-n. Additionally, or alternatively, the system 500 may represent a 16-Hi HBM or TCDRAM system, where N=16. The system 500 may additionally support any quantity of dies in a single stack, and different stacked configurations.

In some examples, the evaluation operation in FIG. 7 may indicate that the evaluation operation was unsuccessful for the circuitry 630-b-4. Based on the unsuccessful evaluation of the circuitry 630-b-4, a manufacturing device may refrain from bonding or stacking additional second components 650 in the second stack.

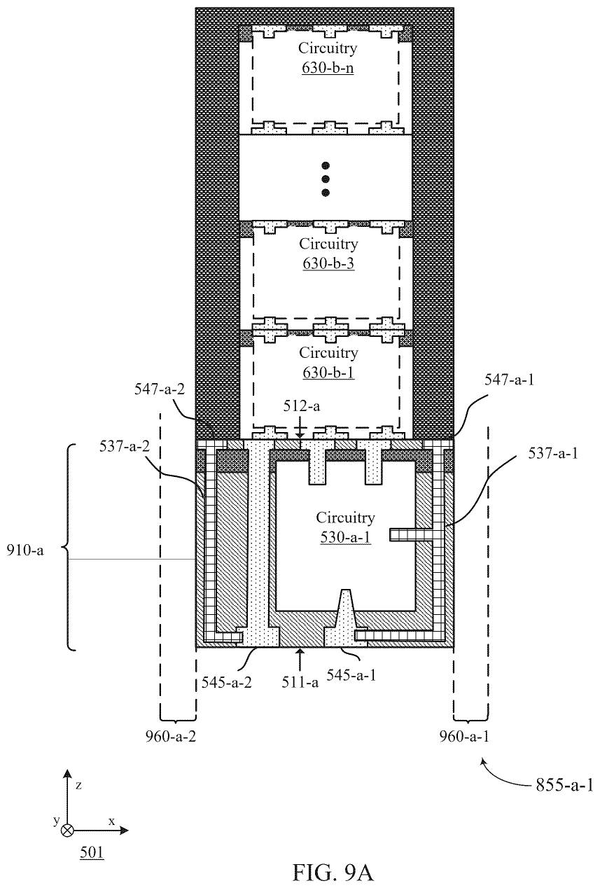

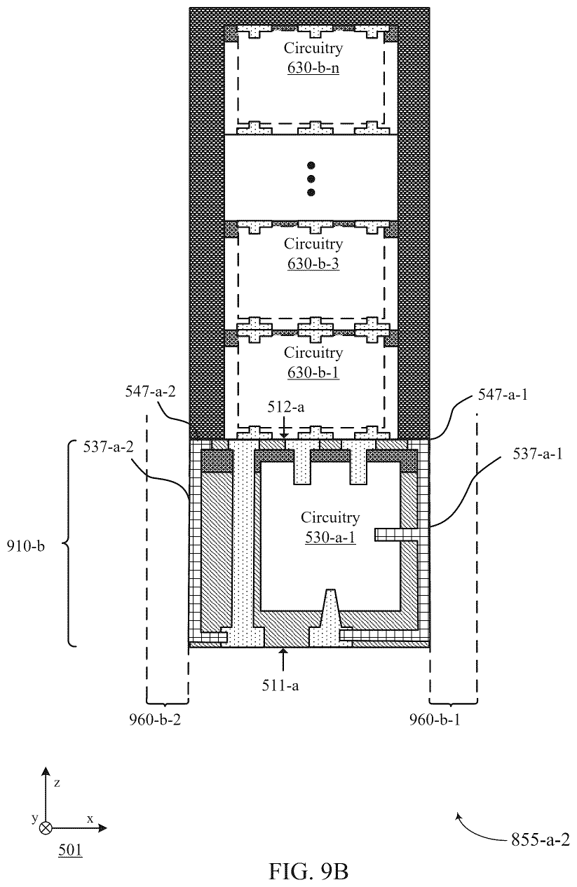

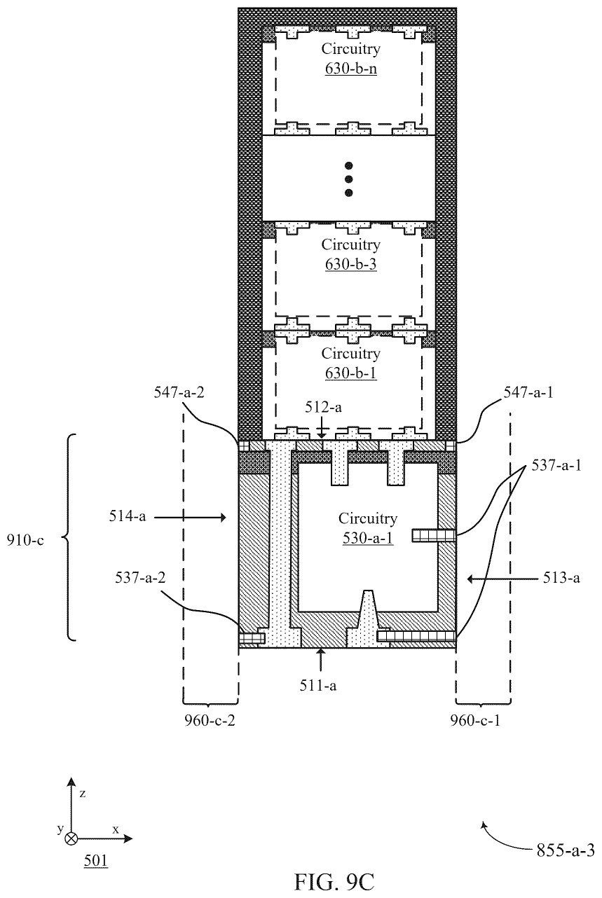

In some examples, the fourth set of manufacturing operations may include a singulation of different units 855 following the completion of die stacking. For example, after the first stack has had N components 650 stacked and the second stack has stopped stacking, the system 500 may include a singulation operation to separate a first semiconductor unit 855-a and a second semiconductor unit 855-b from the semiconductor system 500. The first semiconductor unit 855-a may include the first stack of components and the second semiconductor unit 855-b may include the second stack of components. In some cases, singulation may include “dicing” the system using various techniques (e.g., using a blade or saw, lasers, plasma, or another medium to cut a wafer). In some examples, the singulation process may involve performing a cut along a scribe lane 860-a (e.g., a region of the first component 510 before singulation), or dividing lines between the second components 650. In some examples, the scribe lane 860-a or additional cuts made to the system 500 may be performed along various different locations to enable different final product variations as described with respect to FIGS. 9A-9C.

In some examples, the fourth set of manufacturing operations may include over-mold formation (e.g., after die stacking is complete and before singulation of the different units 855). For example, an over-mold layer 815 (e.g., an over-mold material) may be deposited over the first component 510 and the second components 650, and the semiconductor units 855 may be singulated along with respective portions of the over-mold layer 815 after the depositing. Additionally, or alternatively, an over-mold layer 815 may be deposited after singulation of the different units 855. The fourth set of manufacturing operations may also include debonding the units 855 from the support substrate 505. For example, after the over-mold formation and, in some implementations, after singulation of the semiconductor units 855, respective singulated portions of the first component 510 may be debonded from the support substrate 505 (e.g., for further coupling of each semiconductor unit 855 with other components of one or more packages). Additionally, or alternatively, one or more other components may be removed after the stacking process or during the stacking process. For example, at least a portion of the test pads 547 (among other contacts and features of the layer 520) may be removed after stacking is complete and before over-mold formation. The deposition of the over-mold layer 815, singulation of the semiconductor units 855, and debonding from the support substrate 505, among the other operations of the fourth set of manufacturing operations may be performed in various orders.

In some examples, a semiconductor unit 855 as depicted in FIG. 8 may represent a memory device (e.g., an HBM device, TCDRAM device), or other device, after the manufacturing operations of FIGS. 5-8 are complete. For example, the semiconductor units 855 may be examples of memory devices that may be coupled with a host system or other device in a product. In some other implementations, the semiconductor units 855 may be of include stacked processing components (e.g., stacks of processor dies, stacked processor cores). The semiconductor unit 855-a may be an example of a device at full capability, whereas the semiconductor unit 855-b may represent a device operable at partial capability.

The described techniques for in-situ evaluation, which may leverage test pads 547 on a same surface that die stacking is performed, may reduce semiconductor component loss (e.g., of KGDs which satisfy an evaluation), reduce resource consumption (e.g., time, energy), and reduce manufacturing costs. For example, the semiconductor unit 855-b may include a smaller quantity of second components 650 (e.g., semiconductor dies) than the semiconductor unit 855-a, and may be used at a lower capacity or scrapped before wasting further second components 650. Such processes may support stacking and testing being performed without detaching a supporting structure (e.g., the WSS layer or material). For example, utilizing the conductors 537 and corresponding test pads 547, the one or more evaluation operations (e.g., to test O/S or functionality of dies) described herein may be performed during the stacking process (e.g., after each second component 650 is stacked), among other evaluation operations (e.g., testing of die functionality and to determine KGDs). Further, testing performed after debonding the units 855 or the first component 510 from the support substrate 505 may be omitted or reduced.

FIGS. 9A-9C show examples of semiconductor units 855-a that support techniques for in-situ testing of stacked semiconductor components in accordance with examples as disclosed herein. Each example of a semiconductor unit 855-a may include a respective component 910, which may represent a portion of the first component 510 after singulation. In some cases, each of the components 910 may include at least a portion of the conductors 537-a-1 and 537-a-2, at least a portion of the test pads 547-a-1 and 547-a-2, or both, as described herein.

FIG. 9A shows a semiconductor unit 855-a-1 that may include an entirety of the conductors 537 and test pads 547. For example, the scribe lane 860-a may be positioned so that, after singulation, a component 910-a may include the entirety of the conductors 537-a-1 and 537-a-2 and of the test pads 547-a-1 and 547-a-2. For example, each of the conductors 537-a-1 and 537-a-2 may include a respective first interface at the surface 511-a (e.g., in an xy-plane). In some cases, an interface may be an example of a boundary, extent, or termination of a feature, such as the conductors 537 or test pads 547. For example, the conductors 537-a-1 and 537-a-2 may each be coupled with respective operative contacts 545-a-1 and 545-a-2. The conductors 537-a-1 and 537-a-2 may also include respective second interfaces at another surface of the component 910-a (e.g., in an xy-plane). For example, the conductors 537-a-1 and 537-a-2 may each include the respective test pads 447-a-1 and 447-a-2 having an interface at the surface 512-a at a back side of the substrate 925-a-1.

In some examples, at least a portion of the test pads 547-a-1 and 547-a-2 may be located between scribe lanes 960-a-1 and 960-a-2, which may define singulation locations. The test pads 547-a-1 and 547-a-2 may also be located outside the bonding area of the components 650-a through 650-n. In some examples, the respective second interfaces (e.g., test pads 547) may be coupled with the respective first interfaces (e.g., operative contacts 545-a) via the respective conductors 537 (e.g., the conductors 537-a-1 and 537-a-2 may each include a conductor portion through a remaining portion of the semiconductor substrate 525-a-1). In some examples, one or more of the test pads 547 may include a surface irregularity, such as a probe mark, indicative of a use of test pads 547 for probe evaluations.

FIG. 9B shows semiconductor unit 855-a-2 that may include at least a portion of the conductors 537 and at least a portion of the test pads 547. For example, scribe lanes 960-b-1 and 960-b-2 may be positioned so that after singulation, a component 910-b of the semiconductor unit 855-a may include at least some of the conductor 537-a-1 and the conductor 537-a-2 with at least a portion of the test pads 547-a-1 and 547-a-2. For example, the portions of the test pads 547-a-1 and 547-a-2 (including one or more irregularities, imprints, and discontinuities from probe testing), may remain based on the placement of the scribe lanes 960-b-1 and 960-b-2 (e.g., a portion of the test pads 547 may be cut away or cut through due to dicing). Additionally, or alternatively, a portion of the conductors 537 may be cut away, so that the conductors 537-a-1 and 537-a-2 each include at least a portion of one or more vias and one or more wires of the conductors 537 to remain connected with the portions of the test pads 547 (e.g., including an interface or boundary of conductors 537, test pads 547, or both along a yz-plane).

FIG. 9C shows a semiconductor unit 855-a-3 that may include at least a portion of the conductors 537, at least a portion of the test pads 547, or both. For example, scribe lanes 960-c-1 and 960-c-2 may be positioned so that after singulation, a component 910-c of the semiconductor unit 855-a may include a portion of the conductors 537-a-1 and 537-a-2 and a portion of the test pads 547-a-1 and 547-a-2 (e.g., wiring, vias, or conductive pieces of the conductors 537 and the test pads 547 remaining after other portions are removed during singulation).

In some cases, singulation using the scribe lanes 960-c-1 and 960-c-2 may isolate at least a portion of at least one of the test pads 547 or conductors 537 from the operational contacts 545-a. For example, an entirety of vias of the conductors 537 may be removed, so that the wires or horizontal portions of the conductors 537 remain, which may isolate the remaining portions of the test pads 547 from respective conductors 537 coupled with respective contacts 545-a-1 and 545-a-2 at the front-side surface 511-a. Additionally, or alternatively, a portion of the conductor 537-a-1 may remain which is coupled with the circuitry 530-a-1 directly and may otherwise be isolated from a remaining portion of the corresponding test pad 547-a-1. In such an example, each of the remaining portions of the conductors 537-a-1 and 537-a-2 may include a respective second interface at another surface of the component 910-c. For example, one or more portions of the conductor 537-a-1 may include second interfaces at a surface 513-a (e.g., a surface in a yz-plane) which may intersect with a portion of the substrate 525-a-1, while a remaining portion of the conductor 537-a-2 may include a second interface at a surface 514-a (e.g., a surface in a yz-plane) that may also intersect with remaining portions of the substrate 525-a-1.

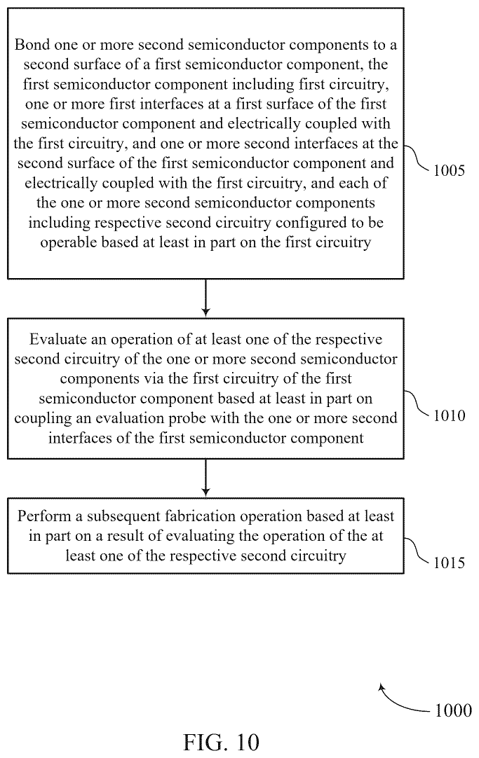

FIG. 10 shows a flowchart illustrating a method 1000 that supports techniques for in-situ testing of stacked semiconductor components in accordance with examples as disclosed herein. The operations of method 1000 may be implemented by a manufacturing system or one or more controllers associated with a manufacturing system. In some examples, one or more controllers may execute a set of instructions to control one or more functional elements of the manufacturing system to perform the described functions. Additionally, or alternatively, one or more controllers may perform aspects of the described functions using special-purpose hardware.

At 1005, the method may include bonding one or more second semiconductor components to a second surface of a first semiconductor component, the first semiconductor component including first circuitry, one or more first interfaces at a first surface of the first semiconductor component and electrically coupled with the first circuitry, and one or more second interfaces at the second surface of the first semiconductor component and electrically coupled with the first circuitry, and each of the one or more second semiconductor components including respective second circuitry configured to be operable based at least in part on the first circuitry.

At 1010, the method may include evaluating an operation of at least one of the respective second circuitry of the one or more second semiconductor components via the first circuitry of the first semiconductor component based at least in part on coupling an evaluation probe with the one or more second interfaces of the first semiconductor component.

At 1015, the method may include performing a subsequent fabrication operation based at least in part on a result of evaluating the operation of the at least one of the respective second circuitry.

In some examples, an apparatus (e.g., a manufacturing system) as described herein may perform a method or methods, such as the method 1000. The apparatus may include features, circuitry, logic, means, or instructions (e.g., a non-transitory computer-readable medium storing instructions executable by one or more controllers to control one or more functional elements of the manufacturing system), or any combination thereof for performing the following aspects of the present disclosure:

Aspect 1: A method or apparatus including operations, features, circuitry, logic, means, or instructions, or any combination thereof for bonding one or more second semiconductor components (e.g., second components 650) to a second surface (e.g., surface 512) of a first semiconductor component (e.g., first component 510), the first semiconductor component including first circuitry (e.g., circuitry 530-a), one or more first interfaces (e.g., operative contacts 545-a) at a first surface (e.g., surface 511) of the first semiconductor component and electrically coupled with the first circuitry, and one or more second interfaces (e.g., test pads 547, portion of conductors 537) at the second surface of the first semiconductor component and electrically coupled with the first circuitry, and each of the one or more second semiconductor components including respective second circuitry (e.g., circuitry 630-b) configured to be operable based at least in part on the first circuitry; evaluating an operation of at least one of the respective second circuitry of the one or more second semiconductor components via the first circuitry of the first semiconductor component based at least in part on coupling an evaluation probe (e.g., probe 665) with the one or more second interfaces of the first semiconductor component; and performing a subsequent fabrication operation based at least in part on a result of evaluating the operation of the at least one of the respective second circuitry.

Aspect 2: The method or apparatus of aspect 1, further including operations, features, circuitry, logic, means, or instructions, or any combination thereof for bonding the first surface of the first semiconductor component to a support substrate (e.g., a support substrate 505) before bonding the one or more second semiconductor components to the first semiconductor component and debonding the first semiconductor component from the support substrate after evaluating the operation of the at least one of the respective second circuitry.

Aspect 3: The method or apparatus of any of aspects 1 through 2, where performing the subsequent fabrication operation includes operations, features, circuitry, logic, means, or instructions, or any combination thereof for bonding one or more third semiconductor components (e.g., second components 650) to the one or more second semiconductor components based at least in part on the evaluation indicating a successful operation, each of the one or more third semiconductor components including respective third circuitry (e.g., circuitry 630-b) configured to be operable based at least in part on the first circuitry.

Aspect 4: The method or apparatus of aspect 3, further including operations, features, circuitry, logic, means, or instructions, or any combination thereof for evaluating an operation of at least one of the respective third circuitry of the one or more third semiconductor components via the first circuitry of the first semiconductor component based at least in part on coupling the evaluation probe with the one or more second interfaces of the first semiconductor component and performing a subsequent second fabrication operation based at least in part on a result of evaluating the operation of the at least one of respective third circuitry.

Aspect 5: The method or apparatus of any of aspects 1 through 4, where performing the subsequent fabrication operation includes operations, features, circuitry, logic, means, or instructions, or any combination thereof for refraining from bonding another semiconductor component (e.g., second components 650) to the one or more second semiconductor components based at least in part on the evaluation indicating an unsuccessful operation.

Aspect 6: The method or apparatus of aspect 1 through 5, further including operations, features, circuitry, logic, means, or instructions, or any combination thereof for bonding one or more third semiconductor components (e.g., second components 650) to the second surface of the first semiconductor component, the first semiconductor component including third circuitry (e.g., circuitry 530-a), one or more third interfaces (e.g., operative contacts 545-a) at the first surface of the first semiconductor component and electrically coupled with the third circuitry, and one or more fourth interfaces (e.g., test pads 547, portion of conductors 537) at the second surface of the first semiconductor component and electrically coupled with the third circuitry, and the one or more third semiconductor components each including respective fourth circuitry (e.g., 630-b) configured to be operable based at least in part on the third circuitry; evaluating an operation of at least one of the respective fourth circuitry of the one or more third semiconductor components via the third circuitry of the first semiconductor component based at least in part on coupling the evaluation probe with the one or more fourth interfaces of the first semiconductor component; and performing the subsequent fabrication operation based at least in part on a result of evaluating the operation of the at least one of the respective fourth circuitry.

Aspect 7: The method or apparatus of aspect 6, where performing the subsequent fabrication operation includes operations, features, circuitry, logic, means, or instructions, or any combination thereof for bonding one or more fourth semiconductor components to the one or more second semiconductor components (second components 650) and refraining from bonding another semiconductor component (e.g., second components 650) to the one or more third semiconductor components.

Aspect 8: The method or apparatus of any of aspects 1 through 7, where each second interface is coupled with a respective one of the first interfaces via a respective conductor (e.g., conductors 537).

Aspect 9: The method or apparatus of aspect 8, where at least one respective conductor includes a conductor portion (e.g., TSVs of a conductors 537) through a semiconductor substrate (e.g., substrate 525) of the first semiconductor component.

Aspect 10: The method or apparatus of any of aspects 8 through 9, where the first circuitry of the first semiconductor component includes a doped portion of a first side (e.g., a front side) of a semiconductor substrate of the first semiconductor component and at least one respective conductor includes a conductor portion (e.g., RDL in layer 520) formed between the second surface of the first semiconductor component and a second side (e.g., a back side) of the semiconductor substrate opposite the first side.

Aspect 11: The method or apparatus of any of aspects 8 through 10, further including operations, features, circuitry, logic, means, or instructions, or any combination thereof for isolating at least a portion of at least one of the second interfaces from the respective first interface based at least in part on severing the respective conductor, the second interface, or both.

Aspect 12: The method or apparatus of any of aspects 1 through 11, where the bonding includes a fusion bonding operation, a thermal compression operation, a mass reflow operation, a hybrid bonding operation, or a combination thereof.

Aspect 13: The method or apparatus of aspects 1 through 12, where one or more of the respective second circuitry includes a respective array of memory cells and the first circuitry includes logic circuitry configured to be operable to access the respective array of memory cells of the one or more of the respective second circuitry.

It should be noted that the methods described herein describe possible implementations, and that the operations and the steps may be rearranged or otherwise modified and that other implementations are possible. Further, portions from two or more of the methods may be combined.

An apparatus is described. The following provides an overview of aspects of the apparatus as described herein:

Aspect 14: An apparatus, including: a first semiconductor component including first circuitry and one or more conductors coupled with the first circuitry, each of the one or more conductors having a respective first interface at a first surface of the first semiconductor component and a respective second interface at another surface of the first semiconductor component; and one or more second semiconductor components bonded with the first semiconductor component on a second surface of the first semiconductor component opposite the first surface of the first semiconductor component, each of the one or more second semiconductor components including respective second circuitry coupled with the first circuitry of the first semiconductor component, and each of the respective second circuitry configured to be operable based at least in part on signaling received via at least one of the one or more conductors of the first semiconductor component.

Aspect 15: The apparatus of aspect 14, where at least one of the one or more conductors has at least a portion of the respective second interface at the second surface of the first semiconductor component outside a portion of the second surface to which the one or more second semiconductor components is bonded.

Aspect 16: The apparatus of aspect 15, where at least one of the respective second interfaces at the second surface of the first semiconductor component comprises a surface deformation (e.g., a probe mark, an imprint).

Aspect 17: The apparatus of any of aspects 14 through 16, where at least one of the one or more conductors has the respective second interface at a third surface (e.g., surfaces 549) of the first semiconductor component that intersects with a semiconductor substrate of the first semiconductor component.

Aspect 18: The apparatus of any of aspects 14 through 17, where at least one of the one or more conductors includes a respective conductor portion through a semiconductor substrate of the first semiconductor component.

Aspect 19: The apparatus of any of aspects 14 through 18, where: the first circuitry of the first semiconductor component includes a doped portion of a first side of a semiconductor substrate of the first semiconductor component; and at least one of the one or more conductors includes a conductor portion formed between the second surface of the first semiconductor component and a second side of the semiconductor substrate opposite the first side.

Aspect 20: The apparatus of any of aspects 14 through 19, further including: one or more third semiconductor components bonded with the first semiconductor component on the second surface of the first semiconductor component, each of the one or more third semiconductor components including respective third circuitry coupled with the first circuitry of the first semiconductor component, and each of the respective third circuitry configured to be operable based at least in part on signaling received via at least one of the one or more conductors of the first semiconductor component.

Aspect 21: The apparatus of any of aspects 14 through 20, where the first semiconductor component includes a first semiconductor die and a second semiconductor die, the first semiconductor die including the first circuitry of the first semiconductor component.

Aspect 22: The apparatus of aspect 21, where the second semiconductor die includes third circuitry, the first circuitry associated with a first logic function the third circuitry associated with a second logic function different from the first logic function.

Aspect 23: The apparatus of any of aspects 21 through 22, where the second semiconductor die includes third circuitry, the apparatus further including: one or more third semiconductor components bonded with the first semiconductor component on the second surface of the first semiconductor component, each of the one or more third semiconductor components including respective fourth circuitry coupled with the third circuitry of the second semiconductor die, and each of the respective fourth circuitry configured to be operable based at least in part on signaling received via at least one of one or more second conductors of the first semiconductor component.

Aspect 24: The apparatus of any of aspects 14 through 23, where: the respective second circuitry of at least one of the one or more second semiconductor components includes a respective array of memory cells; and the first circuitry includes logic circuitry configured to be operable to access the respective array of memory cells of the at least one of the one or more second semiconductor components.

An apparatus is described. The following provides an overview of aspects of the apparatus as described herein:

Aspect 25: An apparatus formed by a process including: bonding one or more second semiconductor components to a second surface of a first semiconductor component, the first semiconductor component including first circuitry, one or more first interfaces at a first surface of the first semiconductor component and electrically coupled with the first circuitry, and one or more second interfaces at the second surface of the first semiconductor component and electrically coupled with the first circuitry, and each of the one or more second semiconductor components including respective second circuitry configured to be operable based at least in part on the first circuitry; evaluating an operation of at least one of the respective second circuitry of the one or more second semiconductor components via the first circuitry of the first semiconductor component based at least in part on coupling an evaluation probe with the one or more second interfaces of the first semiconductor component; and performing a subsequent fabrication operation based at least in part on a result of evaluating the operation of the at least one of the respective second circuitry.

Aspect 26: The apparatus of aspect 25, formed by the process further including: bonding the first surface of the first semiconductor component to a support substrate before bonding the one or more second semiconductor components to the first semiconductor component; and debonding the first semiconductor component from the support substrate after evaluating the operation of the at least one of the respective second circuitry.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (e.g., in conductive contact with, connected with, coupled with) one another if there is any electrical path (e.g., conductive path) between the components that can, at any time, support the flow of signals (e.g., charge, current, voltage) between the components. A conductive path between components that are in electronic communication with each other (e.g., in conductive contact with, connected with, coupled with) may be an open circuit or a closed circuit based on the operation of the device that includes the connected components. A conductive path between connected components may be a direct conductive path between the components or may be an indirect conductive path that includes intermediate components, such as switches, transistors, or other components. In some examples, the flow of signals between the connected components may be interrupted for a time, for example, using one or more intermediate components such as switches or transistors.

The terms “layer” and “level” may refer to an organization (e.g., a stratum, a sheet) of a geometrical structure (e.g., relative to a substrate). Each layer or level may have three dimensions (e.g., height, width, and depth) and may cover at least a portion of a surface. For example, a layer or level may be a three dimensional structure where two dimensions are greater than a third, e.g., a thin-film. Layers or levels may include different elements, components, or materials. In some examples, one layer or level may be composed of two or more sublayers or sublevels.

As used herein, the term “electrode” may refer to an electrical conductor, and in some examples, may be employed as an electrical contact to a memory cell or other component of a memory array. An electrode may include a trace, a wire, a conductive line, a conductive layer, or the like that provides a conductive path between components of a memory array.

The description set forth herein, in connection with the appended drawings, describes example configurations and does not represent all the examples that may be implemented or that are within the scope of the claims. The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Similar components may be distinguished by following the reference label by one or more dashes and additional labeling that distinguishes among the similar components. If just the first reference label is used in the specification, the description is applicable to any one of the similar components having the same first reference label irrespective of the additional reference labels.

The functions described herein may be implemented in hardware, software executed by a processing system (e.g., one or more processors, one or more controllers, control circuitry processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processor. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, that can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or a processor.

The descriptions and drawings are provided to enable a person having ordinary skill in the art to make or use the disclosure. Various modifications to the disclosure will be apparent to the person having ordinary skill in the art, and the techniques disclosed herein may be applied to other variations without departing from the scope of the disclosure. Thus, the disclosure is not limited to the examples and designs described herein but is to be accorded the broadest scope consistent with the principles and novel features disclosed herein.

What is claimed is:

1. An apparatus, comprising:
a first semiconductor component comprising first circuitry and one or more conductors coupled with the first circuitry, each of the one or more conductors having a respective first interface at a first surface of the first semiconductor component and a respective second interface at another surface of the first semiconductor component; and
one or more second semiconductor components bonded with the first semiconductor component on a second surface of the first semiconductor component opposite the first surface of the first semiconductor component, each of the one or more second semiconductor components comprising respective second circuitry coupled with the first circuitry of the first semiconductor component, and each of the respective second circuitry configured to be operable based at least in part on signaling received via at least one of the one or more conductors of the first semiconductor component.

2. The apparatus of claim 1, wherein at least one of the one or more conductors has at least a portion of the respective second interface at the second surface of the first semiconductor component outside a portion of the second surface to which the one or more second semiconductor components is bonded.

3. The apparatus of claim 2, wherein at least one of the respective second interfaces at the second surface of the first semiconductor component comprises a surface deformation.

4. The apparatus of claim 1, wherein at least one of the one or more conductors has the respective second interface at a third surface of the first semiconductor component that intersects with a semiconductor substrate of the first semiconductor component.

5. The apparatus of claim 1, wherein at least one of the one or more conductors comprises a respective conductor portion through a semiconductor substrate of the first semiconductor component.

6. The apparatus of claim 1, wherein:
the first circuitry of the first semiconductor component comprises a doped portion of a first side of a semiconductor substrate of the first semiconductor component; and
at least one of the one or more conductors comprises a conductor portion formed between the second surface of the first semiconductor component and a second side of the semiconductor substrate opposite the first side.

7. The apparatus of claim 1, further comprising:
one or more third semiconductor components bonded with the first semiconductor component on the second surface of the first semiconductor component, each of the one or more third semiconductor components comprising respective third circuitry coupled with the first circuitry of the first semiconductor component, and each of the respective third circuitry configured to be operable based at least in part on signaling received via at least one of the one or more conductors of the first semiconductor component.

8. The apparatus of claim 1, wherein the first semiconductor component comprises a first semiconductor die and a second semiconductor die, the first semiconductor die comprising the first circuitry of the first semiconductor component.

9. The apparatus of claim 8, wherein the second semiconductor die comprises third circuitry, the first circuitry associated with a first logic function the third circuitry associated with a second logic function different from the first logic function.

10. The apparatus of claim 8, wherein the second semiconductor die comprises third circuitry, the apparatus further comprising:
one or more third semiconductor components bonded with the first semiconductor component on the second surface of the first semiconductor component, each of the one or more third semiconductor components comprising respective fourth circuitry coupled with the third circuitry of the second semiconductor die, and each of the respective fourth circuitry configured to be operable based at least in part on signaling received via at least one of one or more second conductors of the first semiconductor component.

11. The apparatus of claim 1, wherein:
the respective second circuitry of at least one of the one or more second semiconductor components comprises a respective array of memory cells; and
the first circuitry comprises logic circuitry configured to be operable to access the respective array of memory cells of the at least one of the one or more second semiconductor components.

12. A method, comprising:
bonding one or more second semiconductor components to a second surface of a first semiconductor component, the first semiconductor component comprising first circuitry, one or more first interfaces at a first surface of the first semiconductor component and electrically coupled with the first circuitry, and one or more second interfaces at the second surface of the first semiconductor component and electrically coupled with the first circuitry, and each of the one or more second semiconductor components comprising respective second circuitry configured to be operable based at least in part on the first circuitry;
evaluating an operation of at least one of the respective second circuitry of the one or more second semiconductor components via the first circuitry of the first semiconductor component based at least in part on coupling an evaluation probe with the one or more second interfaces of the first semiconductor component; and
performing a subsequent fabrication operation based at least in part on a result of evaluating the operation of the at least one of the respective second circuitry.

13. The method of claim 12, further comprising:
bonding the first surface of the first semiconductor component to a support substrate before bonding the one or more second semiconductor components to the first semiconductor component; and
debonding the first semiconductor component from the support substrate after evaluating the operation of the at least one of the respective second circuitry.

14. The method of claim 12, wherein performing the subsequent fabrication operation comprises:
bonding one or more third semiconductor components to the one or more second semiconductor components based at least in part on the evaluation indicating a successful operation, each of the one or more third semiconductor components comprising respective third circuitry configured to be operable based at least in part on the first circuitry.

15. The method of claim 14, further comprising:
evaluating an operation of at least one of the respective third circuitry of the one or more third semiconductor components via the first circuitry of the first semiconductor component based at least in part on coupling the evaluation probe with the one or more second interfaces of the first semiconductor component; and
performing a subsequent second fabrication operation based at least in part on a result of evaluating the operation of the at least one of respective third circuitry.

16. The method of claim 12, wherein performing the subsequent fabrication operation comprises:
refraining from bonding another semiconductor component to the one or more second semiconductor components based at least in part on the evaluation indicating an unsuccessful operation.

17. The method of claim 12, further comprising:
bonding one or more third semiconductor components to the second surface of the first semiconductor component, the first semiconductor component comprising third circuitry, one or more third interfaces at the first surface of the first semiconductor component and electrically coupled with the third circuitry, and one or more fourth interfaces at the second surface of the first semiconductor component and electrically coupled with the third circuitry, and the one or more third semiconductor components each comprising respective fourth circuitry configured to be operable based at least in part on the third circuitry;
evaluating an operation of at least one of the respective fourth circuitry of the one or more third semiconductor components via the third circuitry of the first semiconductor component based at least in part on coupling the evaluation probe with the one or more fourth interfaces of the first semiconductor component; and
performing the subsequent fabrication operation based at least in part on a result of evaluating the operation of the at least one of the respective fourth circuitry.

18. The method of claim 17, wherein performing the subsequent fabrication operation comprises:
bonding one or more fourth semiconductor components to the one or more second semiconductor components; and
refraining from bonding another semiconductor component to the one or more third semiconductor components.

19. The method of claim 12, wherein each second interface is coupled with a respective one of the first interfaces via a respective conductor.

20. The method of claim 19, wherein at least one respective conductor comprises a conductor portion through a semiconductor substrate of the first semiconductor component.

21. The method of claim 19, wherein:
the first circuitry of the first semiconductor component comprises a doped portion of a first side of a semiconductor substrate of the first semiconductor component; and
at least one respective conductor comprises a conductor portion formed between the second surface of the first semiconductor component and a second side of the semiconductor substrate opposite the first side.

22. The method of claim 19, further comprising:
isolating at least a portion of at least one of the second interfaces from the respective first interface based at least in part on severing the respective conductor, the second interface, or both.

23. The method of claim 12, wherein the bonding comprises a fusion bonding operation, a thermal compression operation, a mass reflow operation, a hybrid bonding operation, or a combination thereof.

24. The method of claim 12, wherein:
one or more of the respective second circuitry comprises a respective array of memory cells; and
the first circuitry comprises logic circuitry configured to be operable to access the respective array of memory cells of the one or more of the respective second circuitry.

25. An apparatus formed by a process comprising:
bonding one or more second semiconductor components to a second surface of a first semiconductor component, the first semiconductor component comprising first circuitry, one or more first interfaces at a first surface of the first semiconductor component and electrically coupled with the first circuitry, and one or more second interfaces at the second surface of the first semiconductor component and electrically coupled with the first circuitry, and each of the one or more second semiconductor components comprising respective second circuitry configured to be operable based at least in part on the first circuitry;
evaluating an operation of at least one of the respective second circuitry of the one or more second semiconductor components via the first circuitry of the first semiconductor component based at least in part on coupling an evaluation probe with the one or more second interfaces of the first semiconductor component; and
performing a subsequent fabrication operation based at least in part on a result of evaluating the operation of the at least one of the respective second circuitry.

26. The apparatus of claim 25, formed by the process further comprising:
bonding the first surface of the first semiconductor component to a support substrate before bonding the one or more second semiconductor components to the first semiconductor component; and
debonding the first semiconductor component from the support substrate after evaluating the operation of the at least one of the respective second circuitry.
